(19) United States
(12) Patent Application Publication
(10) Pub. No.: US 2009/0184741 A1
(43) Pub. Date: Jul. 23, 2009

(54) Delay lock loop circuit, phase lock loop circuit, timing generator, semiconductor tester and semiconductor integrated circuit

(76) Inventors: Masakatsu Suda, Tokyo (JP); Daisuke Watanabe, Tokyo (JP)

Correspondence Address: Muramatsu & Associates, 114 Pacifica, Suite 310, Irvine, CA, 92618, US

(21) Appl. No.: 11/663,526

(22) PCT Filed: Aug. 3, 2005
(86) PCT No.: PCT/JP05/14179

§ 371 Date: Mar. 21, 2007

(30) Foreign Application Priority Data
Sep. 21, 2004 (JP) 2004-273931

(51) Int. Cl. H03L 7/06

(52) U.S. Cl. 327/158

(57) ABSTRACT

A delay lock loop circuit and a phase lock loop circuit are designed to reduce a lock-up time, extend a lock range without increasing the number of bits of a counter, and quickly return to a lock target upon deviation from the lock target. There are provided with a plurality of phase comparators 11a, 11b, counters 12a, 12b, and DA converters 13a, 13b. A resolution per unit bit of each of the DA converters 13a, 13b is differentiated. An adder element 14 adds up delay times indicated by delay time signals output from the DA converters 13a, 13b, and a BIAS 15 converts a sum of the delay times into delay times of delay elements of a delay element group 16 and supplies it to an output signal.

### TECHNICAL FIELD

The present invention relates to a delay lock loop (DLL) circuit and a phase lock loop (PLL) circuit for digital control mainly including logical elements, a timing generator in which the DLL is used, a semiconductor tester including this timing generator, and a semiconductor integrated circuit including the PLL.

### BACKGROUND ART

Heretofore, a delay locked loop (DLL) circuit and a phase locked loop (PLL) circuit are each known as one means of a frequency multiplier or the like.

The DLL and PLL circuits are circuits which control and adjust a time difference (a phase difference) between a reference clock signal (an input signal) supplied from the outside and an inner clock signal by circuit technology to realize a high-speed clock access time and a high operation frequency.

As a difference between the DLL and the PLL, for example, the DLL controls a delay time of an inner signal with respect to the input signal, whereas the PLL controls a phase of an output from an internal oscillation circuit with respect to the input signal.

The DLL and PLL have propositions such as reduction of a lock-up time and improvement of precision of a delay amount in view of functions, use purposes and the like of these loops. However, from a viewpoint of solving these propositions, instead of conventional DLL and PLL of analog control, the DLL and PLL of digital control are proposed.

Here, a conventional circuit constitution example of the DLL will be described with reference to FIGS. 28(A), (B). FIG. 28(A) is a block diagram showing a circuit constitution of a conventional DLL 100, and FIG. 28(B) is a graph showing a change of each signal with elapse of time in the conventional DLL 100.

As shown in FIG. 28(A), the conventional DLL 100 includes a phase comparator 110, a counter 120 and a variable delay circuit (DELAY) 130.

The phase comparator 110 inputs an output signal (an output waveform) of the variable delay circuit 130 together with an input signal (an input waveform). Moreover, a value of the output signal is detected in synchronization with the input signal. This detection result is output as a phase signal indicating advance or delay of a phase of the output signal with respect to the input signal ((a), (b) and (c) of FIG. 28(B)).

The counter 120 has a function of a priority encoder, and controls a control signal constituted of a plurality of bits by the phase signal from the phase comparator 110 to output the control signal ((c), (d) of the FIG. 28(B)). This output control signal is sent to the variable delay circuit 130.

The variable delay circuit 130 inputs the control signal and the input signal, and outputs the output signal. Here, in the variable delay circuit 130, the larger the number of the bits indicating “H” in the control signal is, the longer the delay time of the output signal with respect to the input signal becomes. On the other hand, the smaller the number of the bits indicating “H” in the control signal is, the shorter the delay time of the output signal with respect to the input signal becomes.

Next, a specific circuit constitution of the conventional DLL will be described with reference to FIG. 29.

The phase comparator 110 may be constituted using, for example, a D-flip-flop (D-FF) 111.

The counter 120 includes (e.g., 39 stages of) flip-flops 121-1 to 121-n (hereinafter referred to simply as the “flip-flops 121”) as many as the bits of the control signal, and (e.g., 39 stages of) selecting sections 122-1 to 122-n (hereinafter referred to simply as the “selecting sections 122”) as many as the flip-flops 121.

Each flip-flop 121 outputs bit values q (herein, q1 to q39) constituting the control signal one by one.

The selecting sections 122 correspond with the flip-flops 121 one by one, respectively, and select signals to be sent to the corresponding flip-flops 121.

For example, when the phase signal is “H” indicating the delay of the phase, each selecting section 122 selects an output value of the flip-flop 121 of the previous stage to send the value to the corresponding flip-flop 121. On the other hand, when the phase signal is “L” indicating the advance of the phase, each selecting section 122 selects an output value of the flip-flop 121 of the next stage to send the value to the corresponding flip-flop 121.

In consequence, each selecting section 122 increases the number of the bits of “H” of the control signal by one in a case where the phase signal is “H” and decreases the number of the bits of “L” of the control signal by one in a case where the phase signal is “L”.

Moreover, a control signal generated by the counter 120 is sent to the variable delay circuit 130.

It is to be noted that the counter 120 mentioned herein is a priority encoder type counter which increases or decreases, by one, the number of the bits indicating “H” in the control signal in response to the phase signal, and therefore the value of the control signal changes by only one bit once.

The variable delay circuit 130 may be constituted of, for example, a plurality of inverters 131 of a CMOS circuit and variable resistances 132.

Odd stages of the inverters 131 of the CMOS circuit are connected in series as logical gates of reverse outputs, and an output of the last stage is input to the initial stage.

Each of the variable resistances 132 is disposed between the inverter 131 and power voltage sources Vdd, Vss, and the resistances are constituted of resistances as many as the bits of the control signal, connected in parallel with one another; and switching elements connected in series with the resistances, respectively. Here, a transistor is disposed as the switching element, and an on-resistance of a transistor is used as the resistance.

Moreover, the transistors have a one-to-one correspondence with the bit values constituting the control signal. That is, the bit values of the control signal are applied to gate electrodes of the transistors. As a result, the transistor is brought into a conducted state in a case where the corresponding bit value indicates “L”, and brought into a non-conducted state in a case where the value indicates “H”. Moreover, a reverse bit value of the control signal is input into the gate electrode of each transistor disposed between the inverter and the power voltage Vdd.

It is to be noted that in FIG. 29, wiring lines which guide bit signals of the control signals from the flip-flops 121 of the counter 120 to the gate electrodes of the transistors of the variable delay circuit 130 are omitted.

As described above, according to the conventional DLL for the digital control, the circuit is constituted of the logical elements without using any analog circuit. In consequence, reduction of power consumption, reduction of circuit scale and reduction of cost can be achieved.

Furthermore, in the conventional DLL for the digital control, as compared with the conventional DLL for the analog control, it is possible to reduce the number of cycle clocks required from a time when a lock target is exceeded until feedback control is applied. As a result, a loop lock band can be set to be high.

Next, a conventional constitution of the PLL will be described with reference to FIGS. 30(A), (B). The FIG. 28(A) is a block diagram showing a circuit constitution of a conventional PLL 200, and the FIG. 28(B) is a graph showing a change of each signal with elapse of time in the conventional PLL 200.

As shown in the drawing, the conventional PLL 200 includes a phase comparator 210, a counter 220, a ring oscillator (RING OSC) 230 and a frequency demultiplier (a divider) 240.

The phase comparator 210 inputs an input signal (an input waveform) from the outside and a feedback signal from the divider 240, and outputs delay or advance of a phase of the feedback signal with respect to the input signal as a phase signal ((a), (b) and (c) of the FIG. 28(B)).

The counter 220 inputs the phase signal from the phase comparator 210, and controls and outputs a control signal based on this phase signal. The control signal is constituted of a plurality of bits, and “H” or “L” indicated by each bit is controlled in response to the phase signal ((c), (d) of the FIG. 28(B)).

The ring oscillator 230 inputs the control signal from the counter 220, and lowers a self oscillation frequency in a case where this control signal has a large number of bits indicating “H” and a small number of bits indicating “L”. That is, an oscillation period of the output signal is lengthened.

On the other hand, the ring oscillator 230 raises the self oscillation frequency in a case where this control signal has a small number of bits indicating “H” and a large number of bits indicating “L”. That is, the oscillation period of the output signal is shortened.

According to such a constitution, the conventional PLL can achieve the reduction of the power consumption, the reduction of the circuit scale and the reduction of the cost in the same manner as in the conventional DLL.

Furthermore, the number of the cycle clocks can be reduced, and a high loop lock band can be set.

The specific examples of the conventional DLL and PLL have been described above, but various DLLs are proposed in addition to these specific examples.

For example, in a digital DLL including a phase comparison circuit, a counter and a variable delay circuit, the variable delay circuit is constituted by connecting a finely variable delay circuit in which a delay amount can finely be controlled in series with a coarsely variable delay circuit in which the delay amount can coarsely be controlled. These finely variable delay circuit and coarsely variable delay circuit are connected to the counters, respectively, and the delay amounts are controlled independently of each other. Furthermore, the phase comparison circuit contains two pulse selection circuits, and each pulse selection circuit assigns numbers to pulses of the reference signal and the feedback signal, respectively, to thereby identify the pulses corresponding to the reference signal and the feedback signal, respectively (see, e.g., Patent Document 2).

According to such a constitution, precision of the delay amount can be improved, jitters can be reduced, and a time required until locking can be shortened.

Furthermore, another example of the digital DLL is proposed.

For example, in the digital DLL including a phase comparison circuit, a counter and a variable delay circuit, the phase comparison circuit compares a phase of the reference signal with that of a comparison target signal, and outputs a phase difference signal according to the result. The counter successively determines a most significant bit to a least significant bit of a count value in response to the phase difference signal until the phase of the reference signal is synchronized with that of the comparison target signal. After the phase of the reference signal is synchronized with that of the comparison target signal, the count value is controlled from the least significant bit to the most significant bit in response to the phase difference signal (see, e.g., Patent Document 3).

According to such a constitution, since the above operation is switched in the counter, a lock-up time of the DLL can be reduced.

Patent Document 1: International Patent Publication No. WO03/036796;

Patent Document 2: Japanese Patent No. 2970845; and

Patent Document 3: Japanese Patent Application Laid-open No. 2000-124779.

### DISCLOSURE OF THE INVENTION

### Problem to be Solved by the Invention

However, the conventional DLL and PLL have the following problems.

For example, in the DLL disclosed in Patent Document 1 described above, there has been a problem that a counter has an enormous number of bits in a case where a lock range is to be enlarged.

On the other hand, in a case where a change amount (a resolution) of a delay time with respect to a one-bit change of a count value is increased in order to prevent the number of the bits of the counter from being enormous, there has been a problem that a lock-up time cannot sufficiently be shortened.

Furthermore, upon deviation from a lock range due to influences of incoming noises and the like, the count value sticks to a minimum or maximum value, and the delay time cannot further be delayed or advanced.

In addition, since there are many places to be adjusted (calibrated), much measurement is required until locking.

Moreover, the DLL disclosed in Patent Document 2 described above does not have a constitution in which a multiphase CLK is taken at an equal phase interval, and therefore cannot be applied to the following use application.

<Use Application> (1) coarse delay of a timing generator; (2) a local DLL or a local PLL which reduces skew of CLK distribution of LSI; and (3) a multiplier CLK generation circuit and a CLK recovery circuit of a high-speed data transmitter such as SERDES.

Furthermore, in the DLL disclosed in Patent Document 2 described above, a delay element is not realized by multistage connection in which the same circuit is repeated. Therefore, when the circuit is applied to the PLL, the circuit is easily influenced by suction phenomenon (pull-in-noise or tune-in-noise) due to the noise in the vicinity of the oscillation period of VCO of the PLL or the vicinity of a period integer times the period.

Moreover, in the DLL disclosed in Patent Document 3 described above, it is not possible to quickly return to a periphery of a lock target upon deviation from the lock target owing to the influence of the incoming noise or the like.

Furthermore, when the counter is operated in a binary form, a glitch is output, and the circuit cannot be used in an application region where the number of the pulses to be generated is controlled.

The present invention has been developed in view of the above circumstances, and an object of the present invention is to provide a delay lock loop circuit, a phase lock loop circuit, a timing generator, a semiconductor tester and a semiconductor integrated circuit in which it is possible to extend a lock range without increasing the number of bits of a counter, further reduce a lock-up time, and quickly return to a lock target upon deviation from the lock target.

### Means for Solving the Problem

To achieve this object, a delay lock loop circuit of the present invention is a delay lock loop circuit including a delay element group constituted by dependently connecting a plurality of delay elements having an equal delay amount and configured to output an output signal from each stage of the plurality of delay elements, the circuit comprising: a plurality of phase comparators which input an input signal and an output signal and which output a phase signal; a plurality of counters which input the phase signal from the corresponding phase comparator and which output a control signal; a plurality of delay time acquiring sections which input the control signal from the corresponding counter and which output a delay time signal indicating a delay time corresponding to a bit value of this input control signal; an adding section which adds up the delay times indicated by the delay time signals output from the plurality of delay time acquiring sections, respectively; and a delay time control section which converts a sum of the delay times added up by this adding section into the delay time of each delay element of the delay element group, the plurality of delay time acquiring sections being configured to convert a resolution per unit bit concerning the delay time corresponding to the bit value of the control signal into a different resolution.

According to such a constitution of the delay lock loop circuit, this delay lock loop circuit includes the plurality of delay time acquiring sections, and the delay time acquiring sections have the different resolutions, respectively. Therefore, for example, when one of the delay time acquiring sections has a coarse resolution and another delay time acquiring section has a fine resolution, a lock range can be extended without increasing the number of the bits of the counter.

Furthermore, the adding section adds up the delay times indicated by the delay time signals output from the delay time acquiring sections. Therefore, while both of the delay time of the coarse resolution and the delay time of the fine resolution are reflected, the sum of the delay times can be obtained. Therefore, a lock-up time can rapidly be shortened as compared with the resolution is simply enlarged.

In addition, even upon deviation from the lock range due to an influence of an incoming noise or the like, a count value does not stick to a minimum or maximum value, and the delay time can quickly be returned to the lock range.

Furthermore, places to be adjusted (calibrated) are reduced, and measurement until locking can be reduced.

In addition, the delay lock loop circuit of the present invention includes the delay element group constituted by dependently connecting the plurality of delay elements having the equal delay amount and configured to output the output signals from the stages at the equal phase intervals. Therefore, the circuit is usable in the following applications ((1) coarse delay of the timing generator; (2) a local DLL or a local PLL which reduces skew of CLK distribution of LSI; and (3) a multiplier CLK generation circuit and a CLK recovery circuit of a high-speed data transmitter such as SERDES).

Furthermore, even upon the deviation from the lock target due to the influence of the incoming noise or the like, the delay time cannot quickly return to a periphery of the lock target.

In addition, any glitch generated in a case where the counter is operated in a binary form is not output; and the circuit is usable even in an application region where the number of pulses to be generated is controlled.

Moreover, the delay lock loop circuit of the present invention is constituted so that the plurality of phase comparators include first and second phase comparators; the first phase comparator outputs the phase signal indicating one of UP and DOWN based on delay or advance of a phase of the output signal with respect to the input signal; and the second phase comparator outputs the phase signal indicating one of UP, DOWN and HOLD based on delay, advance or equality of the phase of the output signal with respect to the input signal.

According to such a constitution of the delay lock loop circuit, for example, when the first phase comparator has the fine resolution and the second phase comparator has the coarse resolution, the lock range can be extended. Furthermore, the lock-up time can be reduced. In addition, even upon large deviation from the lock target due to a disturbance or the like, the delay time can quickly come close to the lock target.

Moreover, the delay lock loop circuit of the present invention is constituted so that the phase comparator has an automatic calibration circuit which automatically calibrates skews of the input signal and the output signal.

According to such a constitution of the delay lock loop circuit, the skews of the input signal and the output signal can be calibrated automatically, not manually. Therefore, a trouble of measurement until locking can be reduced.

Furthermore, the delay lock loop circuit of the present invention is constituted so that the phase comparator has a first selector circuit which inputs an input signal and an output signal and which selects the input signal in response to input of a calibration signal into a mode terminal and which outputs this selected input signal as a first selection signal; a second selector circuit which inputs an input signal and which outputs this input signal as a second selection signal; a deskew circuit which delays the second selection signal output from this second selector circuit; a data retaining circuit which outputs the phase signal indicating UP or DOWN based on delay or advance of a phase of the first selection signal with respect to the second selection signal; and the automatic calibration circuit; this automatic calibration circuit has a counter which counts up only when the phase signal indicating UP is received from the data retaining circuit to output a count signal; and the deskew circuit delays the second selection signal based on the count signal output from the counter.

According to such a constitution of the delay lock loop circuit the skews of the input signal and the output signal can automatically be calibrated. Therefore, the trouble of measurement until locking can be reduced.

Moreover, the delay lock loop circuit of the present invention comprises a voltage generator which applies different current amounts to the plurality of delay time acquiring sections, respectively, to set the resolution per unit bit of each of the delay time acquiring sections to a different value.

According to such a constitution of the delay lock loop circuit, the plurality of delay time acquiring sections can have different resolutions. Therefore, the reduction of the lock-up time and the extension of the lock range can be achieved.

Furthermore, the delay lock loop circuit of the present invention is constituted so that a delay time of a high-order resolution is applied to an output signal by use of a first phase comparator which outputs a phase signal indicating one of UP, DOWN and HOLD, a first counter which receives the phase signal from this first phase comparator and a first delay time acquiring section in which the voltage generator determines the resolution per unit bit in accordance with a comparatively long delay time; and a delay time of a low-order resolution is applied to an output signal by use of a second phase comparator which outputs a phase signal indicating one of UP and DOWN, a second counter which receives the phase signal from this second phase comparator and a second delay time acquiring section in which the voltage generator determines the resolution per unit bit in accordance with a comparatively short delay time.

According to such a constitution of the delay lock loop circuit, the first phase comparator, the first counter and the first delay time acquiring section can apply a coarse delay time to the output signal. On the other hand, the second phase comparator, the second counter and the second delay time acquiring section can apply a fine delay time to the output signal. Therefore, as compared with a DLL including only one phase comparator, only one counter and only one delay time acquiring section, the lock-up time can rapidly be reduced. In addition, the lock range can be extended without increasing the number of the bits of the counter.

Moreover, the delay lock loop circuit of the present invention is constituted so that the adding section is connected to current paths indicating the delay time signals output from the plurality of delay time acquiring sections via wired OR, and sends, to the delay time control section, a sum of currents as the delay time added up.

According to such a constitution of the delay lock loop circuit, the delay times indicated by the delay time signals output from the plurality of delay time acquiring sections can be added up. Therefore, both of the delay time having the coarse resolution and the delay time having the fine resolution can be applied to the output signal. Therefore, the lock-up time can be reduced.

Furthermore, the delay lock loop circuit of the present invention is constituted so that the delay time control section has a first transistor through which a current indicating the delay time added up by the adding section flows and a second transistor which is a delay element; and the first transistor is current-mirror connected to the second transistor.

According to such a constitution of the delay lock loop circuit, since the first transistor is current-mirror connected to the second transistor, tr/tf (the delay time with respect to an operation time) of each delay element of the delay element group is an inclination proportional to the sum of the delay times added up by the adding section, and the delay time to be applied to the output signal can be changed.

Moreover, the delay lock loop circuit of the present invention is constituted so that the first delay time acquiring section has a small resolution, and the second delay time acquiring section has a large resolution, the delay lock loop circuit further comprising: a controller circuit which sends a signal to set a count value to a half value to the first counter and sends a signal to count up or down to the second counter based on the phase signal input from the second phase comparator and/or a digit shift signal input from the first counter, the first counter being configured to send the digit shift signal to the controller circuit, when the first counter counts up or down based on the phase signal from the first phase comparator and the count value is above or below a predetermined range.

Here, the delay time corresponding to a difference between a minimum value and the half value of the first counter or the delay time corresponding to a difference between a maximum value and the half value of the first counter is equal to the delay time corresponding to one bit of the second counter.

According to such a constitution of the delay lock loop circuit, overflow or underflow of the counter can be avoided without increasing the number of the bits of the counter.

The delay lock loop circuit according to claims 1 to 8 includes a plurality of sets of phase comparators, counters and DA converters, and the resolutions of the sets are differentiated (at least a set having a large resolution and a set having a small resolution are made). In consequence, the delay time can quickly come close to the lock target in response to generation of the noise.

In addition, when the noise having a large amplitude is followed, the overflow (the count value exceeds the predetermined range) and the underflow (the count value is below the predetermined range) occur in the counter. To avoid this, it is considered that the number of the bits of the counter is increased. However, this has a demerit that a circuit scale increases.

To solve the problem, the delay lock loop circuit includes a controller circuit (a controller) which controls an operation of each counter of each set. Moreover, when the count value of the first counter (of the set having the small resolution) exceeds the predetermined range and the second counter (of the set having the large resolution) outputs the phase signal indicating HOLD, the count value of the first counter is set to the half value, and the second counter is allowed to count up (carry) or down (borrow).

As described above, carrying/borrowing of a delay component having the small resolution and a delay component having the large resolution is performed. In consequence, a lock range can be broadened without increasing the circuit scale of the counter, and the overflow and the underflow of the counter can be avoided.

Moreover, the delay lock loop circuit of the present invention is constituted so that the first counter sends a carry digit shift signal to the controller circuit, when the first counter counts up based on the phase signal input from the first phase comparator and indicating UP and the count value is above the predetermined range; the controller circuit sends a half signal to the first counter to set the count value to the half value and sends the signal indicating UP to the second counter to count up, when receiving the carry digit shift signal and receiving the phase signal indicating HOLD from the second phase comparator; the first counter sets the count value to the half value when receiving the half signal; and the second counter counts up when receiving the signal indicating UP.

According to such a constitution of the delay lock loop circuit, when the count value of the first counter is above the predetermined range, the count value of this first counter is set to the half value based on the half signal from the controller circuit, and the second counter counts up based on the UP signal from the controller circuit. In consequence, the overflow of the counter can be avoided.

Moreover, the delay lock loop circuit of the present invention is constituted so that the first counter sends a borrow digit shift signal to the controller circuit, when the first counter counts down based on the phase signal input from the first phase comparator and indicating DOWN and the count value is below the predetermined range; the controller circuit sends the half signal to the first counter to set the count value to the half value and sends the signal indicating DOWN to the second counter to count down, when receiving the borrow digit shift signal and receiving the phase signal indicating HOLD from the second phase comparator; the first counter sets the count value to the half value when receiving the half signal; and the second counter counts down when receiving the signal indicating DOWN.

According to such a constitution of the delay lock loop circuit, when the count value of the first counter is below the predetermined range, the count value of this first counter is set to the half value based on the half signal from the controller circuit, and the second counter counts down based on the DOWN signal from the controller circuit. In consequence, the underflow of the counter can be avoided.

Furthermore, the delay lock loop circuit of the present invention is constituted so that the controller circuit sends the half signal to the first counter and sends the signal indicating UP to the second counter, when the phase signal indicating UP is input from the second phase comparator; the first counter sets the count value to the half value when receiving the half signal; and the second counter counts up when receiving the signal indicating UP.

According to such a constitution of the delay lock loop circuit, when the output signal of the delay element group delays as much as +t1 (delay) or more from 0 (1 cycle delay) with respect to the input signal, the count value of the first counter is set to the half value, and the second counter can count up. In consequence, the delay time can quickly come close to the lock target.

In addition, the delay lock loop circuit of the present invention is constituted so that the controller circuit sends the half signal to the first counter and sends the signal indicating DOWN to the second counter, when the phase signal indicating DOWN is input from the second phase comparator; the first counter sets the count value to the half value when receiving the half signal; and the second counter counts down when receiving the signal indicating DOWN.

According to such a constitution of the delay lock loop circuit, when the output signal of the delay element group advances as much as −t1 (advance) or more from 0 (1 cycle delay) with respect to the input signal, the count value of the first counter is set to the half value, and the second counter can count down. In consequence, the delay time can quickly come close to the lock target.

Moreover, a phase lock loop circuit of the present invention is a phase lock loop circuit including a delay element group constituted by dependently connecting a plurality of delay elements having an equal delay amount and configured to output an output signal from each stage of the plurality of delay elements, the circuit comprising: a plurality of phase comparators which input an input signal and an output signal and which output a phase signal; a plurality of counters which input the phase signal from the corresponding phase comparator and which output a control signal; a plurality of delay time acquiring sections which input the control signal from the corresponding counter and which output a delay time signal indicating a delay time corresponding to a bit value of this input control signal; an adding section which adds up the delay times indicated by the delay time signals output from the plurality of delay time acquiring sections, respectively; and a delay time control section which converts a sum of the delay times added up by this adding section into the delay time of each delay element of the delay element group, the plurality of delay time acquiring sections being configured to convert a resolution per unit bit concerning the delay time corresponding to the bit value of the control signal into a different resolution.

According to such a constitution of the phase lock loop circuit, this circuit includes the plurality of delay time acquiring sections each having the different resolution per unit bit. Therefore, the lock-up time can rapidly be shortened as compared with a phase lock loop circuit including only one delay time acquiring section. In addition, even upon large deviation from the lock target due to the disturbance the like, the delay time can quickly be returned to the lock target.

Furthermore, since the delay element is realized by multistage connection in which the same circuit is repeated, the circuit is not easily influenced by suction phenomenon (pull-in-noise or tune-in-noise) due to the noise in the vicinity of an oscillation period of VCO of a PLL or the vicinity of a period integer times the period.

Here, suction is a phenomenon of a RING OSC or the like in which a periodically incoming noise is synchronized with passage of a pulse through a specific position in the RING OSC, and a frequency of the RING OSC is locked in integer times (or a fraction of an integer) the frequency of the incoming noise.

When rising and falling of the pulse in the RING OSC are unbalanced, an interference amount received by each portion of the RING OSC differs, and the incoming noise is synchronized especially with a delayed rising/falling portion.

When the same circuit constitution and an equal capacity load are assumed, the same rising/falling occurs. Even when the periodically incoming noise interferes with any portion, an equal interference amount is generated. Therefore, any specific portion is not bound in synchronization with the incoming noise, and any suction phenomenon does not occur.

Moreover, the phase lock loop circuit of the present invention is constituted so that the plurality of phase comparators include first and second phase comparators; the first phase comparator outputs the phase signal indicating one of UP and DOWN based on delay or advance of a phase of the output signal with respect to the input signal; and the second phase comparator outputs the phase signal indicating one of UP, DOWN and HOLD based on delay, advance or equality of the phase of the output signal with respect to the input signal.

According to such a constitution of the phase lock loop circuit, when the first phase comparator copes with the delay time of the fine resolution and the second phase comparator copes with the delay time of the coarse resolution, the delay time can quickly come close to the lock target.

Furthermore, the phase lock loop circuit of the present invention is constituted so that the phase comparator has an automatic calibration circuit which automatically calibrates skews of the input signal and the output signal.

According to such a constitution of the phase lock loop circuit, the skews of the input signal and the output signal can be calibrated automatically without performing any manual operation. Therefore, a trouble of measurement performed until locking can be reduced.

In addition, the phase lock loop circuit of the present invention is constituted so that the phase comparator has a first selector circuit which inputs an input signal and an output signal and which selects the input signal in response to input of a calibration signal into a mode terminal and which outputs this selected input signal as a first selection signal; a second selector circuit which inputs an input signal and which outputs this input signal as a second selection signal; a deskew circuit which delays the second selection signal output from this second selector circuit; a data retaining circuit which outputs the phase signal indicating UP or DOWN based on delay or advance of a phase of the first selection signal with respect to the second selection signal; and the automatic calibration circuit; this automatic calibration circuit has a counter which counts up only when the phase signal indicating UP is received from the data retaining circuit to output a count signal; and the deskew circuit delays the second selection signal based on the count signal output from the counter.

According to such a constitution of the phase lock loop circuit, the skews of the input signal and the output signal can automatically be calibrated by the automatic calibration circuit. Therefore, the trouble of measurement performed until the locking can be reduced.

Moreover, the phase lock loop circuit of the present invention comprises a voltage generator which applies different current amounts to the plurality of delay time acquiring sections, respectively, to set the resolution per unit bit of each of the delay time acquiring sections to a different value.

According to such a constitution of the phase lock loop circuit, different resolutions of the delay time can be determined for the plurality of delay time acquiring sections, respectively. Therefore, for example, the sum of the delay times obtained by adding up the delay times of the coarse resolution and the fine resolution can be converted into the delay time of each delay element and applied to the output signal. In consequence, the reduction of the lock-up time can be achieved.

Furthermore, the phase lock loop circuit of the present invention is constituted so that a delay time of a high-order resolution is applied to an output signal by use of a first phase comparator which outputs a phase signal indicating one of UP, DOWN and HOLD, a first counter which receives the phase signal from this first phase comparator and a first delay time acquiring section in which the voltage generator determines the resolution per unit bit in accordance with a comparatively long delay time; and a delay time of a low-order resolution is applied to an output signal by use of a second phase comparator which outputs a phase signal indicating one of UP and DOWN, a second counter which receives the phase signal from this second phase comparator and a second delay time acquiring section in which the voltage generator determines the resolution per unit bit in accordance with a comparatively short delay time.

According to such a constitution of the phase lock loop circuit, a combination of the first phase comparator, the first counter and the first delay time acquiring section can apply a coarse-resolution delay time to the output signal. On the other hand, a combination of the second phase comparator, the second counter and the second delay time acquiring section can apply a fine-resolution delay time to the output signal.

In consequence, the lock-up time can largely be reduced.

Moreover, the phase lock loop circuit of the present invention is constituted so that the adding section is connected to current paths indicating the delay time signals output from the plurality of delay time acquiring sections via wired OR, and sends, to the delay time control section, a sum of currents as the delay time added up.

According to such a constitution of the phase lock loop circuit, both of the delay time of the coarse resolution and the delay time of the fine resolution can be applied to the output signal. Therefore, the lock-up time can be reduced. Even upon deviation from the lock target, the delay time can quickly be returned to the lock target

Furthermore, the phase lock loop circuit of the present invention is constituted so that the delay time control section has a first transistor through which a current indicating the delay time added up by the adding section flows and a second transistor which is a delay element; and the first transistor is current-mirror connected to the second transistor.

According to such a constitution of the phase lock loop circuit, the ratio tr/tf of the delay element has an inclination which is proportional to the sum of the delay times added up by the adding section, and the delay amount can be changed.

Moreover, the phase lock loop circuit of the present invention is constituted so that the first delay time acquiring section has a small resolution, and the second delay time acquiring section has a large resolution, the phase lock loop circuit further comprising: a controller circuit which sends a signal to set a count value to a half value to the first counter and sends a signal to count up or down to the second counter based on the phase signal input from the second phase comparator and/or a digit shift signal input from the first counter, the first counter being configured to send the digit shift signal to the controller circuit, when the first counter counts up or down based on the phase signal from the first phase comparator and the count value is above or below a predetermined range.

Here, the delay time corresponding to a difference between a minimum value and the half value of the first counter or the delay time corresponding to a difference between a maximum value and the half value of the first counter is equal to the delay time corresponding to one bit of the second counter.

According to such a constitution of the phase lock loop circuit, overflow or underflow of the counter can be avoided without increasing the number of the bits of the counter.

The phase lock loop circuit according to claims 14 to 21 includes a plurality of sets of phase comparators, counters and DA converters, and the resolutions of the sets are differentiated (at least a set having a large resolution and a set having a small resolution are made). In consequence, the delay time can quickly return to a periphery of the lock target in response to generation of a noise.

In addition, when the noise having a large amplitude is followed, the overflow and the underflow occur in the counter. To avoid this, it is considered that the number of the bits of the counter is increased. However, this has a demerit that a circuit scale increases.

To solve the problem, the phase lock loop circuit includes the controller circuit (a controller) which controls an operation of each counter of each set. Moreover, when the count value of the first counter (of the set having the small resolution) exceeds the predetermined range and the second counter (of the set having the large resolution) outputs the phase signal indicating HOLD, the count value of the first counter is set to the half value, and the second counter is allowed to count up or down.

As described above, carrying/borrowing of a delay component having the small resolution and a delay component having the large resolution is performed. In consequence, a lock range can be broadened without increasing the circuit scale of the counter, and the overflow and the underflow of the counter can be avoided.

Moreover, the phase lock loop circuit of the present invention is constituted so that the first counter sends a carry digit shift signal to the controller circuit, when the first counter counts up based on the phase signal input from the first phase comparator and indicating UP and the count value is above the predetermined range; the controller circuit sends a half signal to the first counter to set the count value to the half value and sends the signal indicating UP to the second counter to count up, when receiving the carry digit shift signal and receiving the phase signal indicating HOLD from the second phase comparator; the first counter sets the count value to the half value when receiving the half signal; and the second counter counts up when receiving the signal indicating UP.

According to such a constitution of the phase lock loop circuit, when the count value of the first counter is above the predetermined range, the count value of this first counter is set to the half value based on the half signal from the controller circuit, and the second counter counts up based on the UP signal from the controller circuit. In consequence, the overflow of the counter can be avoided.

Moreover, the phase lock loop circuit of the present invention is constituted so that the first counter sends a borrow digit shift signal to the controller circuit, when the first counter counts down based on the phase signal input from the first phase comparator and indicating DOWN and the count value is below the predetermined range; the controller circuit sends the half signal to the first counter to set the count value to the half value and sends the signal indicating DOWN to the second counter to count down, when receiving the borrow digit shift signal and receiving the phase signal indicating HOLD from the second phase comparator; the first counter sets the count value to the half value when receiving the half signal; and the second counter counts down when receiving the signal indicating DOWN.

According to such a constitution of the phase lock loop circuit, when the count value of the first counter is below the predetermined range, the count value of this first counter is set to the half value based on the half signal from the controller circuit, and the second counter counts down based on the DOWN signal from the controller circuit. In consequence, the underflow of the counter can be avoided.

Furthermore, the phase lock loop circuit of the present invention is constituted so that the controller circuit sends the half signal to the first counter and sends the signal indicating UP to the second counter, when the phase signal indicating UP is input from the second phase comparator; the first counter sets the count value to the half value when receiving the half signal; and the second counter counts up when receiving the signal indicating UP.

According to such a constitution of the phase lock loop circuit, when the output signal of the delay element group delays as much as +t1 (delay) or more from 0 (1 cycle delay) with respect to the input signal, the count value of the first counter is set to the half value, and the second counter can count up. In consequence, the delay time can quickly come close to the lock target.

In addition, the phase lock loop circuit of the present invention is constituted so that the controller circuit sends the half signal to the first counter and sends the signal indicating DOWN to the second counter, when the phase signal indicating DOWN is input from the second phase comparator; the first counter sets the count value to the half value when receiving the half signal; and the second counter counts down when receiving the signal indicating DOWN.

According to such a constitution of the phase lock loop circuit, when the output signal of the delay element group advances as much as −t1 (advance) or more from 0 (1 cycle delay) with respect to the input signal, the count value of the first counter is set to the half value, and the second counter can count down. In consequence, the delay time can quickly come close to the lock target.

Moreover, a timing generator of the present invention is a timing generator comprising: a delay lock loop circuit including a variable delay circuit constituted by connecting a plurality of stages of logical gates in series; and a delay selecting section which selects an output of one of the logical gates to output a delay signal, the delay lock loop circuit being the delay lock loop circuit according to any one of claims 1 to 13.

According to such a constitution of the timing generator, precision of a delay amount to be applied to the signal output from this timing generator can be improved.

In a conventional timing generator, a coarse delay circuit has been used in which the number of the gate stages is switched to add the delay amount.

For example, when REFCLK has a period of 4 ns, a coarse delay amount of 4 ns is required. Assuming that a temperature fluctuation is 0.1%/° C. to 0.15%/° C. and a voltage fluctuation is 0.05%/mV to 0.10%/mV, in a case where there are fluctuations of 5° C. and 50 mV, a CMOS circuit has the following fluctuation of the delay amount:

5° C.×4 ns×(0.1%/° C. to 0.15%/° C.)=20 ps to 30 ps (Equation 1);

50 mV×4 ns×(0.05%/mV to 0.10%/mV)=100 ps to 200 (Equation 2); and

total: 120 ps to 230 ps.

When the coarse delay amount is provided with a DLL, feedback control is applied to the power voltage fluctuation and the temperature fluctuation so as to suppress the fluctuation of the delay time. Therefore, instead of obtaining the above total of 120 ps to 230 ps, jitters (several ps) generated while the DLL follows the amount can be reduced, and an effect of improving precision is obtained.

Moreover, in conventional coarse delay, the delay time fluctuates in a range of 0.6 to 1.6 folds with respect to a standard device. Therefore, a circuit which converts digital delay time data into a coarse delay control signal (a circuit in which data is stored in a table→a linearized memory) has been required.

On the other hand, in a circuit such as a DLL circuit of the present invention in which REFCLK is equally divided, the digital delay time data as data for switching multiphase CLK can be used as it is. Therefore, the linearized memory is not required, and a circuit scale can be reduced.

Furthermore, a timing generator of the present invention is a timing generator comprising: a phase lock loop circuit including a variable delay circuit constituted by connecting a plurality of stages of logical gates in series; and a delay selecting section which selects an output of one of the logical gates to output a delay signal, the phase lock loop circuit being the phase lock loop circuit according to any one of claims 14 to 26.

According to such a constitution of the timing generator, the precision of the delay amount to be applied to the signal output from this timing generator can be improved in the same manner as in a case where the DLL (the DLL according to claims 1 to 8) of the present invention is disposed in the timing generator.

In addition, a semiconductor tester of the present invention is a semiconductor tester comprising: a timing generator which outputs a delay clock signal obtained by delaying a reference clock signal for a predetermined time; a pattern generator which outputs a test pattern signal in synchronization with the reference clock signal; a waveform shaping unit which shapes the test pattern signal in accordance with a device to be tested to send the signal to the device to be tested; and a logical comparator which compares a response output signal of the device to be tested with an expected value data signal, the timing generator being the timing generator according to claim 27 or 28.

According to such a constitution of the semiconductor tester, since a timing of each section of a device is made in response to the delay clock signal provided with a highly precise delay amount, measurement precision of the semiconductor tester can be improved.

Moreover, a semiconductor integrated circuit of the present invention is a semiconductor integrated circuit comprising: a plurality of delay lock loop circuits having an equal oscillation frequency; and wiring lines which distribute reference clock signals having a frequency lower than the oscillation frequency to the delay lock loop circuits, each delay lock loop circuit being the delay lock loop circuit according to any one of claims 1 to 13.

According to such a constitution of the semiconductor integrated circuit, since CLK transmission at a long distance is performed at a low frequency and multiplication is performed at a local portion by use of the DLL, a circuit scale and power consumption of a transmitting portion can be reduced. Since a small number of stages of buffers are entirely required, skews can be reduced.

This is because, when the high-frequency CLK transmission is performed along the long distance in LSI, unlike low-frequency CLK transmission, a measure to shorten a buffer interval and reduce a load capacity or increase a driving capability of each buffer is required. Even if any measure is taken, the circuit scale and the power consumption increase. Since a difference of the number of the stages of the buffers increases between blocks, the skews increase.

Furthermore, a semiconductor integrated circuit the present invention is a semiconductor integrated circuit comprising: a plurality of phase lock loop circuits having an equal oscillation frequency; and wiring lines which distribute reference clock signals having a frequency lower than the oscillation frequency to the phase lock loop circuits, each phase lock loop circuit being the phase lock loop circuit according to any one of claims 14 to 26.

According to such a constitution of the semiconductor integrated circuit, since CLK transmission at a long distance is performed at a low frequency and multiplication is performed at a local portion by use of the PLL, a circuit scale and power consumption of a transmitting portion can be reduced. Since a small number of stages of buffers are entirely required, skews can be reduced.

### EFFECT OF THE INVENTION

As described above, according to the present invention, a plurality of phase comparators, counters and delay time acquiring sections are arranged, a resolution per unit bit of each of the plurality of delay time acquiring sections is differentiated, and a lock-up time can largely be reduced.

In addition, a delay time can quickly return to a lock target even upon large deviation from the lock target due to a disturbance and the like.

Furthermore, a lock range can be extended without increasing the number of bits of the counter.

### BRIEF DESCRIPTION OF THE DRAWINGS

FIG. 1 is a circuit constitution diagram showing a constitution of a delay lock loop circuit according to a first embodiment of the present invention;

FIG. 2 is a circuit constitution diagram showing a constitution of a first phase comparator;

FIG. 3 is an explanatory view showing an operation of the first phase comparator;

FIG. 4 is an explanatory view showing skews of an input signal and an output signal of the first phase comparator;

FIG. 5 is a circuit constitution diagram showing a constitution of a second phase comparator;

FIG. 6 is an explanatory view showing an operation of the first phase comparator;

FIG. 7 is an explanatory view showing the skews of the input signal and the output signal of the first phase comparator;

FIG. 8 is a circuit constitution diagram showing constitutions of a second phase comparator and an automatic calibration circuit;

FIG. 9 is a circuit constitution diagram showing a constitution of a counter;

FIG. 10 is a circuit constitution diagram showing a constitution of a DA converter and the like;

FIG. 11 is an explanatory view showing an adjustment state of a phase relation of the DA converter;

FIG. 12 is a graph showing an adjustment result of a phase;

FIG. 13 is a circuit constitution diagram showing a specific constitution of a delay element, a) shows a circuit constitution of a single delay element, and b) shows a circuit constitution of a differential delay element;

FIG. 14 is a graph showing a delay amount to be applied to a delay clock signal, (a) is a graph of one type of multi-bit DAC, showing that a current value corresponding to digital data of the DAC is 0.6 to 1.6 folds, depending on fluctuations, (b) is a graph showing that a current value corresponding to digital data of a fine DAC is 0.6 to 1.6 folds, depending on fluctuations, in a case where the DAC is divided into fine and coarse DACs, and (c) is a graph showing that a current value corresponding to digital data of the coarse DAC is 0.6 to 1.6 folds, depending on the fluctuations, in a case where the DAC is divided into the fine and coarse DACs;

FIG. 15 is a circuit constitution diagram showing a constitution of a delay lock loop circuit according to a second embodiment of the present invention;

FIG. 16 is a waveform diagram showing an operation of a phase comparator (PD1, PD2) of the delay lock loop circuit according to the second embodiment;

FIG. 17 is a table of true value indicating an operation of a counter (CTR1) of the delay lock loop circuit according to the second embodiment;

FIG. 18 is a table of true value indicating an operation of a counter (CTR2) of the delay lock loop circuit according to the second embodiment;

FIG. 19 is a table of true value indicating an operation of a controller circuit of the delay lock loop circuit according to the second embodiment;

FIG. 20 is an explanatory view showing an operation of a counter (CTR1, CTR2) of the delay lock loop circuit according to the second embodiment;

FIG. 21 is a graph showing simulation results of a conventional delay lock loop circuit and the delay lock loop circuit of the second embodiment, respectively, (a) shows a simulation result of the delay lock loop circuit of the first embodiment, and (b) shows a simulation result of the delay lock loop circuit of the second embodiment;

FIG. 22 is a circuit constitution diagram showing a constitution of a phase lock loop circuit according to the first embodiment of the present invention;

FIG. 23 is a circuit constitution diagram showing a constitution of a phase lock loop circuit according to the second embodiment of the present invention;

FIG. 24 is a circuit constitution diagram showing a constitution of a semiconductor tester of the present invention;

FIG. 25 is a circuit constitution diagram showing a constitution of a timing generator of the present invention;

FIG. 26 is a circuit constitution diagram showing a constitution of a semiconductor integrated circuit of the present invention;

FIG. 27 is a circuit constitution diagram showing another constitution of the semiconductor integrated circuit of the present invention;

FIG. 28(A) is a circuit constitution diagram showing a constitution of a conventional delay lock loop circuit, and (B) is a graph showing a change with elapse of time in each signal of the conventional delay lock loop circuit;

FIG. 29 is a circuit constitution diagram showing an example of a specific circuit constitution of the conventional delay lock loop circuit; and

FIG. 30(A) is a circuit constitution diagram showing a constitution of a conventional phase lock loop circuit, and (B) is a graph showing a change with elapse of time in each signal of the conventional phase lock loop circuit.

### DESCRIPTION OF REFERENCE NUMERALS

10 delay lock loop circuit (DLL)
11a, 11b phase comparators
12a, 12b counters
13a, 13b DA converters
14 adder element
15 BIAS
16 delay element group
20 phase lock loop circuit (PLL)
21a, 21b phase comparators
22a, 22b counters
23a, 23b DA converters
24 adder element
25 BIAS
26 delay element group
27 frequency demultiplier (divider)
30 semiconductor tester
40a, 40b semiconductor integrated circuits
50 delay lock loop circuit (DLL)
51a, 51b phase comparators
52a, 52b counters
53a, 53b DA converters
54 adder element
55 BIAS
56 delay element group
57 controller circuit
60 phase lock loop circuit (PLL)
61a, 61b phase comparators
62a, 62b counters
63a, 63b DA converters
64 adder element
65 BIAS
66 delay element group
67 frequency demultiplier (divider)
68 controller circuit

### BEST MODE FOR CARRYING OUT THE INVENTION

Preferable embodiments of a delay lock loop circuit (DLL), a phase lock loop circuit (PLL), a timing generator, a semiconductor tester and a semiconductor integrated circuit according to the present invention will hereinafter be described with reference to the drawings.

### [DLL]

### First Embodiment of DLL

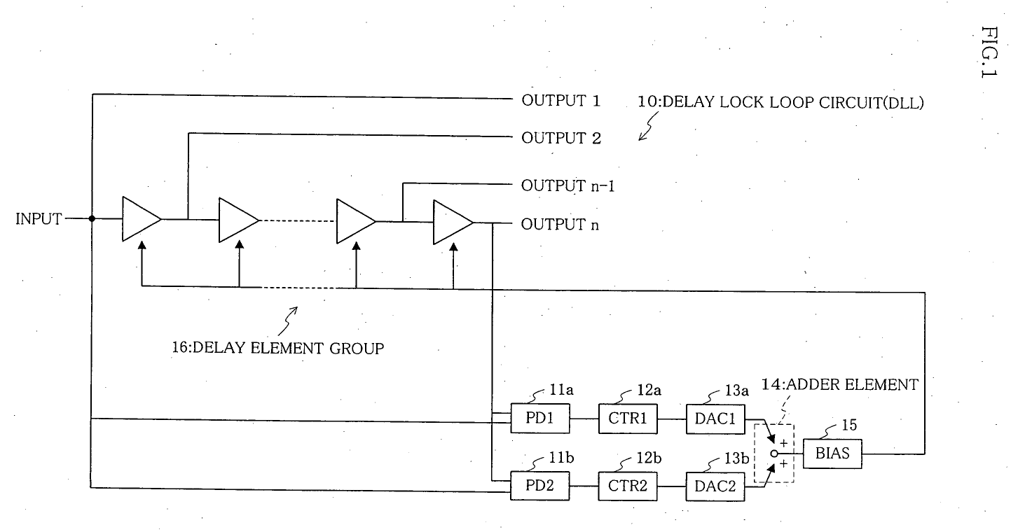

First, a first embodiment of a DLL of the present invention will be described with reference to FIG. 1.

The drawing is a circuit constitution diagram showing a constitution of the DLL of the present embodiment.

As shown in the drawing, a DLL 10 includes phase comparators (PD) 11a, 11b; counters (CTR) 12a, 12b; DA converters (DAC) 13a, 13b; an adder element 14; a delay time control section (BIAS) 15; and a delay element group 16.

Here, the phase comparators 11a, 11b input an input signal to be input into the delay element group 16 and an output signal to be output from the delay element group 16, detect a phase between these signals, and outputs this detection result as a phase signal.

In the present embodiment, there are two phase comparators 11a, 11b.

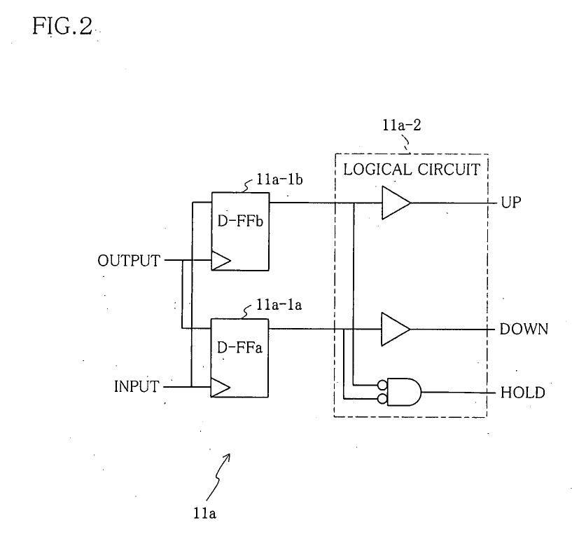

First, a specific circuit constitution example of the phase comparator 11a will be described with reference to FIG. 2.

As shown in the drawing, the phase comparator (a second phase comparator) 11a has two D-FFs 11a-1 (D-FFa (11a-1a), D-FFb (11a-1b)) and a logical circuit 11a-2.

The D-FFa (11a-1a) inputs an output signal into a DATA terminal and an input signal into a CLOCK terminal (a CK terminal). On the other hand, the D-FFb (11a-1b) inputs an input signal into a DATA terminal and an output signal into a CL terminal. That is, the input signal and the output signal are input into the D-FFa (11a-1a) and the D-FFb (11a-1b) so that the signals are replaced with each other in the DATA terminal and the CK terminal.

The D-FFa (11a-1a) inputs a comparison CLK (the output signal) and a comparison target CLK (the input signal), and outputs a flag (control) signal indicating whether or not to allow the counter 12a to count down (DOWN).

The D-FFb (11a-1b) inputs a comparison CLK (the input signal) and a comparison target CLK (the output signal), and outputs a flag (control) signal indicating whether or not to allow the counter 12a to count up (UP).

The logical circuit 11a-2 outputs a flag (phase) signal indicating one of UP, DOWN and HOLD based on the flag (control) signal from the D-FFa (11a-1a) or D-FFb (11a-1b).

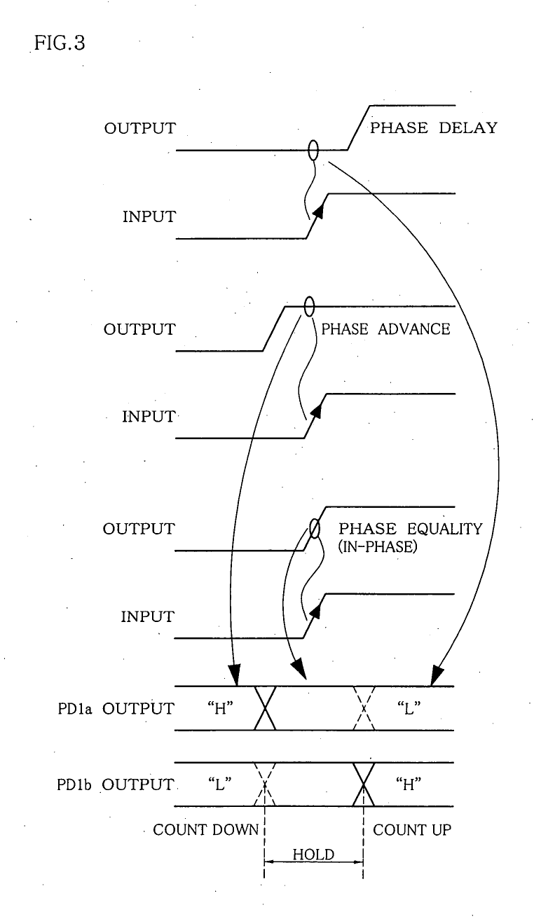

An operation of this logical circuit 11a-2 will be described with reference to FIG. 3.

As shown in the drawing, the logical circuit 11a-2 inputs a flag (control) signal (a flag (control) signal indicating “L”) which does not allow the counter 12a to count down from, for example, the D-FFa (11a-1a) (a “PD1a output” in the drawing). On the other hand, when a flag (control) signal (a flag (control) signal indicating “H”) which allows the counter 12a to count up is input from the D-FFb (11a-1b) (a “PD1b output” in the drawing), a flag (phase) signal which allows the counter 12a to count up is output.

On the other hand, the logical circuit 11a-2 inputs a flag (control) signal (a flag (control) signal indicating “L”) which does not allow the counter 12a to count up from the D-FFb (11a-1b) (a “PD1b output” in the drawing). In addition when a flag (control) signal (a flag (control) signal indicating “H”) which allows the counter 12a to count down is input from the D-FFa (11a-1a) (a “PD1a output” in the drawing), a flag (phase) signal which allows the counter 12a to count down is output.

Moreover, the logical circuit 11a-2 outputs a flag (phase) signal of HOLD (or toggle) in a case where both of the flag (control) signals from two D-FFs 11a-1 indicate “L”.

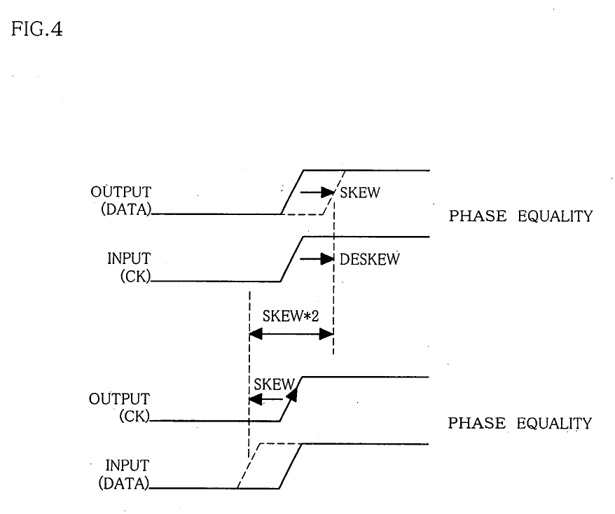

Here, in two D-FFs 11a-1 (D-FFa (11a-1a), D-FFb (11a-1b)), there are skews of CK input and DATA input, and the CK input and the DATA input are replaced with each other. Therefore, a phase difference as a logical change point between the two D-FFs 11a-1 is a sum (the skew is doubled with the same D-FF) of the skews of the two D-FFs 11a-l (a “HOLD” segment of the “PD1a output” and the “PD1b output”, see FIG. 4). When the skew is used, or a hold width is made in a variable delay circuit or the like, an operation is performed as shown in FIG. 3.

It is to be noted that solid lines of FIG. 4 indicate a phase relation between the D-FFs 11a-l at a time when it is judged that a phase of CK meets that of DATA in a case where there is not any skew in DATA and CLK.

However, in actual, there are skews in DATA and CLK. Therefore, the phase relation between the D-FFs 11a-1 at a time when it is judged that the phase of CK meets that of DATA deviates to a position shown by broken lines in the drawing.

It is to be noted that, when DATA and CLK are replaced with each other, the phase relation deviates in an opposite direction.

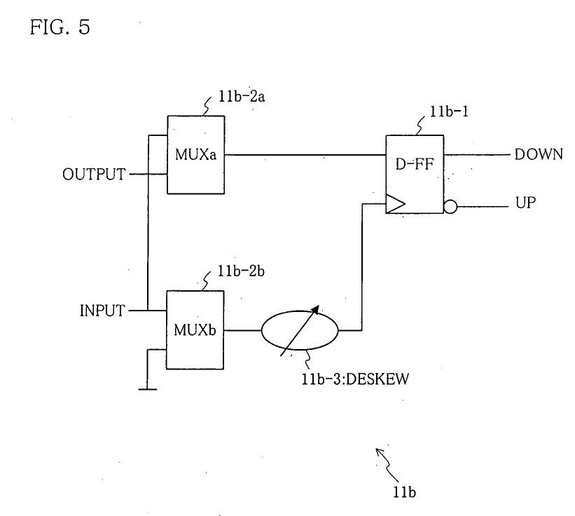

As shown in FIG. 5, the phase comparator (a first phase comparator) 11b has a D-FF 11b-1; an MUXa (11b-2a) (a multiplexor, a selector circuit and a selecting section) having an output terminal thereof connected to a DATA terminal of the D-FF 11b-l; an MUXb (11b-2b) having an output terminal side thereof connected to a CK terminal of the D-FF 11b-1; and a deskew circuit (DESKEW) 11b-3 connected between the DATA terminal of the D-FF 11b-1 and the output terminal of the MUXa (11b-2a).

The D-FF 11b-1 inputs a comparison CLK (a signal from the MUXa (11b-2a)) into the DATA terminal and a comparison target CLK (a signal from the MUXb (11b-2b)) into the CK terminal, respectively, and outputs a flag (phase) signal which allows the counter 12b to count up or down.

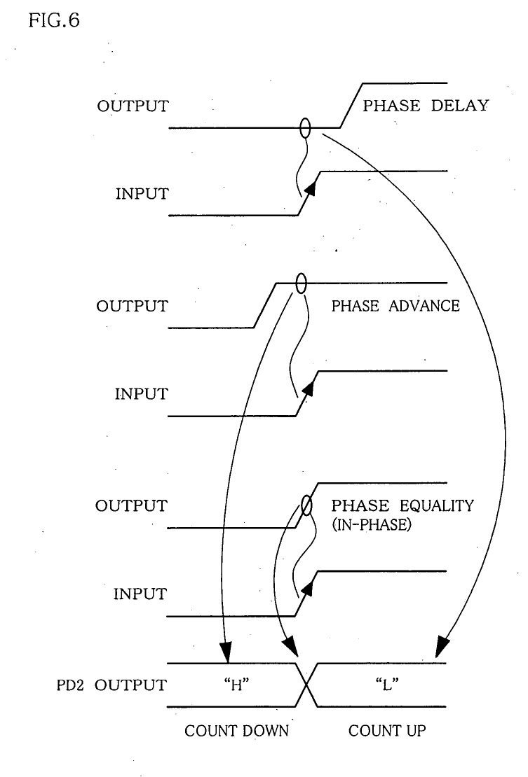

An operation of the phase comparator 11b is shown in FIG. 6.

As shown in the drawing, the phase comparator 11b has three operation modes (phase delay, phase advance and in-phase modes). It is to be noted that the D-FF 11b-1 operates at a rising edge.

In the phase delay mode (an uppermost stage of the drawing), a delay output signal (the “output” of the same stage) is one period or more behind a delay input signal (the “input” of the same stage). This phase relation surpasses “L”.

In the phase advance mode (a second stage of the drawing), a delay output signal (the “output” of the same stage) is one period or more ahead of a delay input signal (the “input” of the same stage). This phase relation surpasses “H”.

In the in-phase mode (a third stage of the drawing), a delay output signal (the “output” of the same stage) is just one period behind a delay input signal (the “input” of the same stage). It is uncertain whether this phase relation surpasses a level of “H” or “L”, or an intermediate value is indicated, depending on a state (a logical level) before the D-FF 11b-1.

A fourth stage of the drawing collectively indicates the above three types of mode. The D-FF 11b-1 outputs “L” on a delay side and “H” on an advance side as delay output signals, respectively, via a position of just one-period delay.

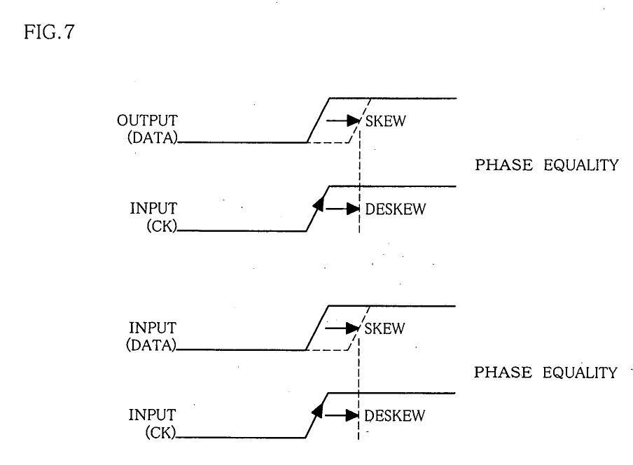

Moreover, an example to adjust (calibrate) skews of the CK terminal and the DATA terminal of the D-FF 11b-1 is shown in FIG. 7.

An upper stage of the drawing indicates that, even when a phase of a CK input of the D-FF 11b-1 meets that of a DATA input, a boundary of output logic is not achieved, “L” is output (see the uppermost stage and the fourth stage of FIG. 6), the DATA input is shifted to a broken line, and then the boundary of the output logic is achieved. In this case, when the deskew circuit 11b-3 shifts the phase of the CK input to the broken line, the phase of the CK input agrees with that of the DATA input, and this agreement point is the boundary of the output logic.

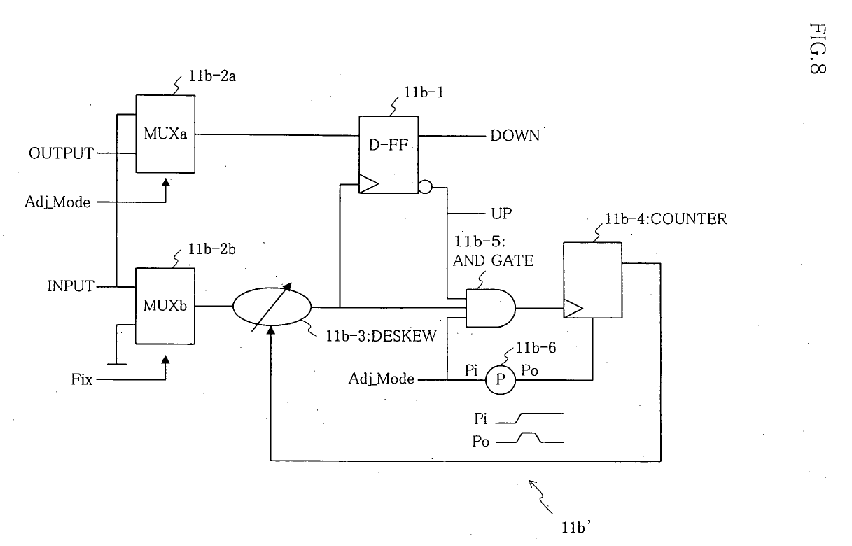

Examples of an adjustable function of this deskew circuit 11b-3 include a function capable of inputting the same waveform into the CK input and the DATA input of the D-FF 11b-1 (FIG. 5 and a lower stage of FIG. 7); and a function of varying a value of the deskew circuit 11b-3 in accordance with the output logic of the D-FF 11b-1. The latter function can be realized as a program. However, for example, when a circuit (an automatic skew calibration circuit 11b′) shown in FIG. 8 is realized, an adjusting signal is simply input for a certain period to complete calibration.

The automatic skew calibration circuit 11b′ is a circuit which automatically calibrates skews of an input signal and an output signal. As shown in FIG. 8, the circuit has a D-FF (11b-l); an MUXa (11b-2a); an MUXb (11b-2b); a deskew circuit (DESKEW) 11b-3; a counter (COUNTER) 11b-4; and an AND gate 11b-5.

The D-FF (a data retaining circuit) (11b-1) inputs an output signal (a first selection signal) from the MUXa (11b-2a) into a DATA terminal, and an output signal (a second selection signal) from the deskew circuit 11b-3 into a CK terminal. Moreover, a phase signal indicating UP or DOWN is output based on delay or advance of a phase of the first selection signal with respect to the second selection signal.

The MUXa (a first selector circuit) (11b-2a) inputs both of an input signal and an output signal, selects the input signal upon input of a calibration signal into a mode terminal, and outputs this selected input signal as the first selection signal.

The MUXb (a second selector circuit) (11b-2b) inputs an input signal, and outputs this input signal as the second selection signal.

The deskew circuit 11b-3 delays the second selection signal output from the MUXb (11b-2b). The deskew circuit 11b-3 delays the second selection signal based on a count signal from the counter 11b-4.

The counter 11b-4 counts up only when receiving the phase signal indicating UP from the D-FF (11b-1), and outputs the count signal.

In the automatic skew calibration circuit 11b′ having such a constitution, when “H” is input into the mode signal (Adj_Mode), the following operations (1) to (3) are performed:

(1) the same waveform is input into the D-FF (11b-1) (MUX switching);

(2) the CLK to be input into the D-FF (11b-1) can be counted up upon receiving an output of data of the D-FF (11b-1); and

(3) a value of the counter 11b-4 is cleared (a deskew value min) upon receiving a rising edge of the mode signal.

Moreover, when an output logical level of the D-FF (11b-1) changes from “L” to “H” owing to a change of a delay amount of the deskew circuit 11b-3, any CLK is not input into the counter 11b-4, and a count-up operation stops.

With elapse of a sufficiently long time after the count-up operation ends, when the mode signal is set to “L”, the DLL 10 is brought into an operation mode to lock.

The deskew circuit 11b-3 on an input side is connected to an output terminal of the MUXb 11b-2b. On the other hand, the deskew circuit on an output side is connected to the CK terminal of the D-FF 11b-1.

As described above, this deskew circuit 11b-3 adjusts a previous stage of the CK terminal of the D-FF 11b-1 so that a point where the input phase of the CK terminal of the D-FF 11b-1 meets that of the DATA terminal is a boundary between “H” and “L” of output data.

Design needs to be assured beforehand so that the phase relation to output “L” is obtained at a time when the delay of the deskew circuit 11b-3 is set to be minimum and that the phase relation to output “H” is obtained at a time when the delay of the deskew circuit is set to be maximum.

It is to be noted that in FIG. 8, the deskew circuit 11b-3 is inserted on a CK terminal side of the D-FF 11b-1, but this is not limited to the CK terminal side, and the deskew circuit may be inserted on a DATA side.

The counters 12a, 12b input flag (phase) signals from the corresponding phase comparators 11a, 11b, and output control signals.

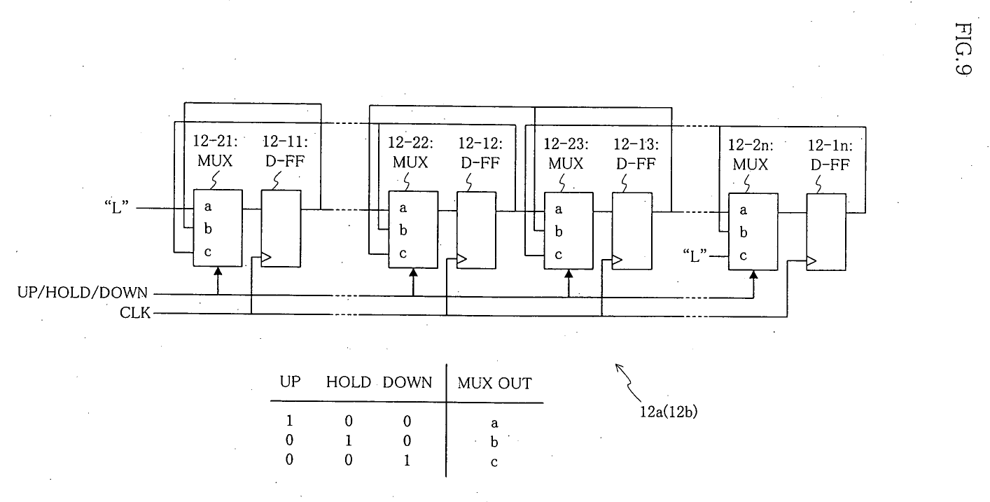

A specific circuit constitution of this counter 12a (12b) is shown in FIG. 9.

As shown in the drawing, the counter 12a (12b) includes (e.g., 39 stages of) D-FFs 12-11 to 12-1n (hereinafter referred to simply as the “D-FFs 12-1”) as many as bits of the control signal; and (e.g., 39 stages of) selecting sections (MUX: selector circuits) 12-21 to 12-2n (hereinafter referred to simply as the “selecting sections 12-2”) as many as these D-FFs 12-1.

Each flip-flop 12-1 outputs bit values q constituting the control signal one by one.

The selecting sections 12-2 have a one-to-one correspondence with the flip-flops 12-1, and select a signal to be sent to the corresponding D-FF 12-1.

In such a constitution, the flag (phase) signals of the phase comparators 11a, 11b are inputted into a control (“UP/HOLD/DOWN” in the drawing) of the counters 12a, 12b of a priority encoder type.

In a case where the flag (phase) signal output from the phase comparator 11a and indicating UP indicates flag=1, the counter 12a performs a function of a shift register which shifts low-order “H” of the D-FFs 11a-1 toward a high order. On the other hand, in a case where the signal indicating DOWN indicates flag=1, the counter performs a function of a shift register which shifts high-order “L” of the D-FFs 11a-1 toward the low order. Furthermore, in a case where the signal indicating HOLD indicates flag=1, the counter does not perform any shift operation, and holds data of each of the D-FFs 11a-1.

The counter 12b has a circuit constitution similar to that of the counter 12a.

However, the phase comparator 11b does not output any flag (phase) signal indicating “HOLD”. Therefore, the counter 12b performs one of (a) inputting “L” into a HOLD input and connecting “L” to a b-terminal of the selecting section 12-2 and (b) removing a function of selecting the b-terminal from the selecting section 12-2. In addition, the counter performs an operation similar to that of the counter 12a.

The DA converters (delay time acquiring sections) 13a, 13b are connected to rear stages of the corresponding counters 12a, 12b, respectively. That is, the DA converter 13a is connected to the rear stage of the counter 12a, and the DA converter 13b is connected to the rear stage of the counter 12b.

Moreover, the DA converter 13a (a second delay time acquiring section) obtains a delay time (an analog amount) corresponding to each bit (a digital amount) of the control signal output from the counter 12a, and the DA converter 13b (a first delay time acquiring section) obtains a delay time corresponding to each bit of the control signal output from the counter 12b.

Here, it is assumed that each of the DA converters 13a, 13b has a different weight (resolution) per bit.

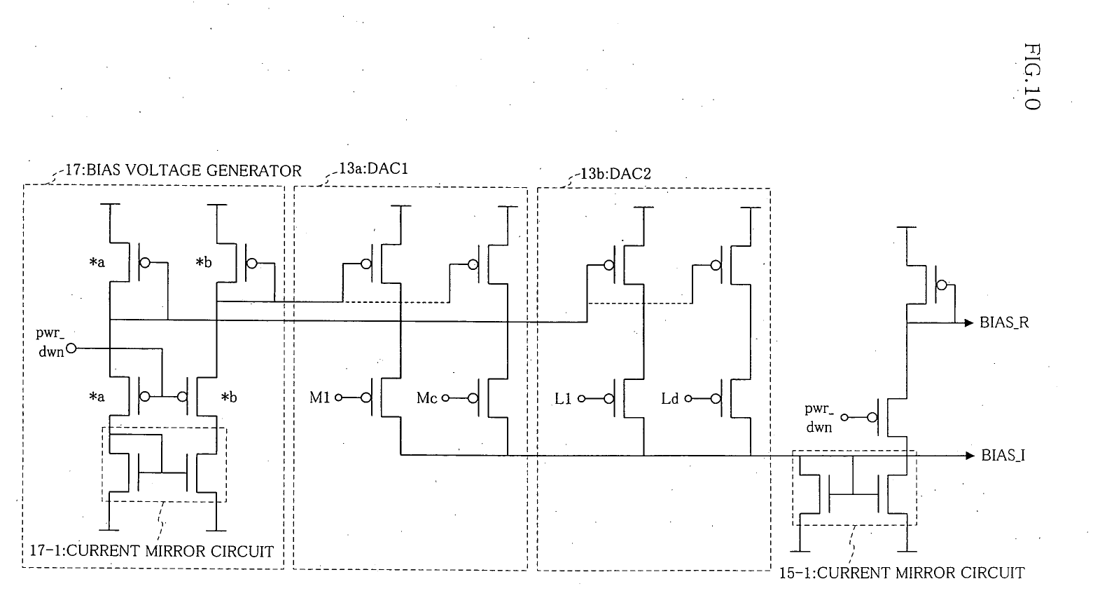

Specific examples of circuit constitutions of the DA converters 13a, 13b and circuit constitutions around the converters are shown in FIG. 10.

Each bit is connected to the current DAC of FIG. 10 so as to generate currents in proportion to the number of “H” of the control signal output from the counters 12a, 12b.

The DA converters 13a, 13b has vertically stacked two stages of Pch transistors more than bit numbers of the counters, and are connected in parallel between a power source on a positive side and a wired-OR node (a summing point of the DAC). An Nch transistor connected to a diode is constituted between the summing point of the DA converters 13a, 13b and a power source on a negative side.

The upper transistor of the transistors vertically stacked in two stages is equivalent to a current source which receives an equal bias voltage, and functions so as to pass an equal current. On the other hand, the lower transistor is equivalent to an analog switch, and is ON/OFF controlled in response to the output signal of the counter.

Therefore, at the summing point of the DAC, the currents generated by the current sources and analog switches arranged in parallel are added up, and the current flows through the Nch transistor in proportion to the value of the counter.

Moreover, as shown in the drawing, the DA converters 13a, 13b are connected to a BIAS voltage generator (BIAS GEN) 17 which determines a current amount of one bit of each of the DA converters 13a, 13b.

Assuming that the current amount of one bit of the DA converter 13a is “Ia”, current mirror connection (a current mirror circuit 17-1) of the BIAS voltage generator 17 determines the current amount of one bit of the DA converter 13b as “Ib=a/b×Ia”.

When current paths (delay time signals) of the DA converters 13a, 13b are wired-or (wired OR) connected, a sum of the currents of the DA converters 13a, 13b enters the Nch transistor (an adder element (an adding section) 14).

Moreover, in a case where the Nch transistor through which the total current of the DA converters 13a, 13b flows is connected to the transistor of the delay element via the current mirror connection (a current mirror circuit 15-1), tr/tf (the delay time to an operation time) of the delay element has an inclination in proportion to the sum of the currents of the DA converters 13a, 13b, and the delay amount changes.

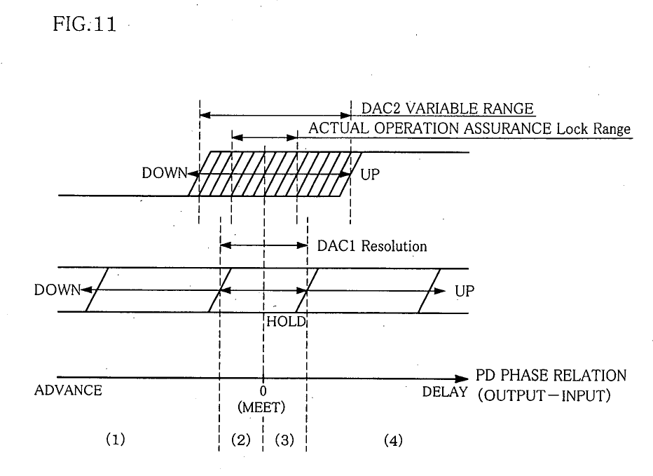

Here, it is preferable that two DA converters 13a, 13b having different resolutions are designed as shown in FIG. 11 so that the DLL 10 of the present embodiment obtains an effect of reduction of a lock-up time and the like.

A variable range of the DA converter 13b is set to be larger than a region where voltage and temperature fluctuations which would be generated in an actual device can be covered. The region where the voltage and temperature fluctuations which would be generated in the actual device can be covered is shown as “actual operation assurance lock range” in FIG. 11.

A step of moving the DA converter 13b increases or decreases (the counter counts UP/DOWN) the current amount with a fine resolution as shown by hatching in the drawing.

The phase comparator 11 is designed so as to issue a flag of HOLD between the “actual operation assurance lock range” and the “DAC2 variable range”. The DA converter 13a increases or decreases (the counter counts UP/DOWN) the current amount with a coarse resolution externally from a segment where the HOLD flag is issued as shown by hatching.

In a region (a phase relation) (1) of the drawing, since a phase largely advances ahead of the target, the DA converter 13a decreases the current (the counter counts down), the DA converter 13b decreases the current (the counter counts down), and feedback control is performed so as to, largely increase the delay amount.

In a region (a phase relation) (2) of the drawing, since the phase slightly advances ahead of the target, the DA converter 13a maintains the current (the counter holds), the DA converter 13b decreases the current (the counter counts down), and feedback control is performed so as to slightly increase the delay amount.

In a region (a phase relation) (3) of the drawing, since the phase is slightly behind the target, the DA converter 13a maintains the current (the counter holds), the DA converter 13b increases the current (the counter counts up), and feedback control is performed so as to slightly decrease the delay amount.

In a region (a phase relation) (4) of the drawing, since the phase is largely behind the target, the DA converter 13a increases the current (the counter counts up), the DA converter 13b increases the current (the counter counts up), and feedback control is performed so as to largely decrease the delay amount.

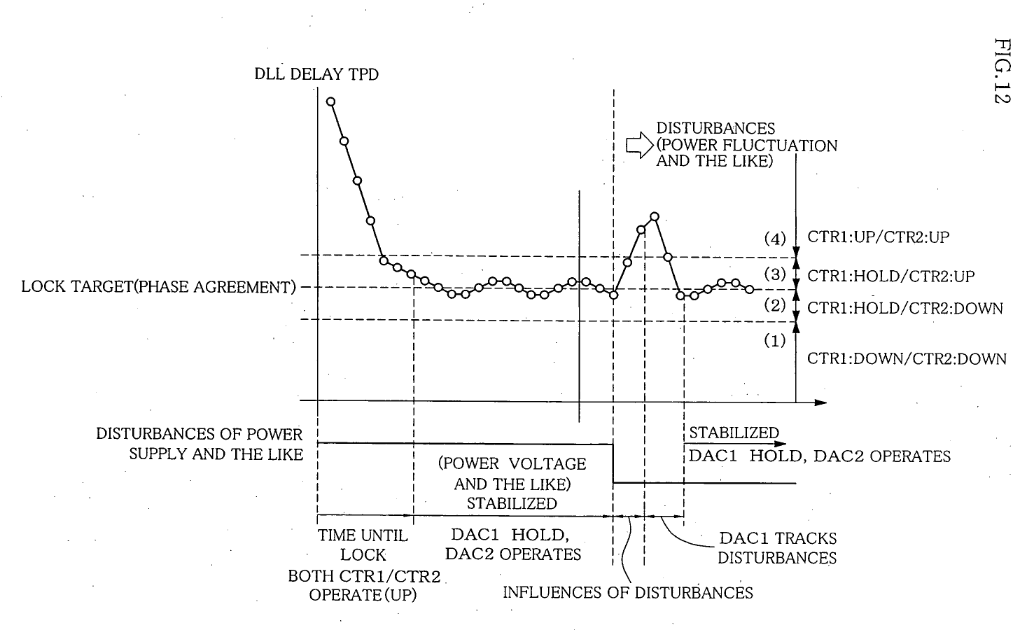

Furthermore, this respect will be described with reference to FIG. 12. The drawing is a graph indicating an adjustment result of the phase.

It is assumed that a counter value is minimum in a feedback operation mode (or at a time when power is turned on).

Since the delay amount increases with respect to the lock target owing to a small current amount, both of the counters 12a, 12b count up, and the feedback control is performed so that the phase comes close to the lock target (a time of the region (4)→Lock).

When the phase comes close to the lock target to such an extent that the phase comparator 11a outputs HOLD (the region (3)), the counter 12a holds, the feedback control is continuously applied to the counter 12b until the lock target is exceeded (until the phase enters the region (2)), and the counter 12b counts up.

When the lock target is exceeded (the phase enters the region (2)), the feedback control is performed so that the phase comes close to the lock target, the counter 12a holds, and the counter 12b counts down.

When the power voltage, temperature and the like are stabilized, the feedback control is performed so that the only counter 12b counts up or down so as to pulsate centering on the lock target.

When disturbances of the power voltage, temperature and the like are generated, the delay amount fluctuates. In the regions (2) and (3), the feedback control is applied so that the counter 12a holds and the only counter 12b counts up or down. At this time, since a delay time change amount includes an only change amount of the DA converter 13b, the amount decreases (micro tracking).

When the delay amount fluctuates to the regions (1) and (4), both of the counters 12a and 12b count up or down, and the feedback control is applied. At this time, since the delay time change amount is obtained by adding up the change amounts of the DA converters 13a, 13b, the amount increases (tracking of a large amount).

Here, a function or a role of BIAS will be described.

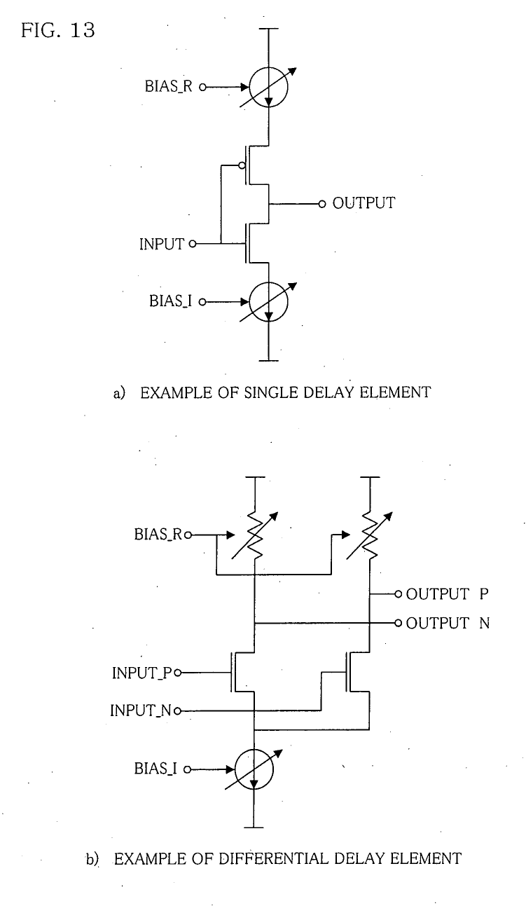

Single Delay Element (FIG. 13(a))

An upper current source is realized by current mirror connection to a Pch transistor in response to BIAS_R.

A lower current source is realized by current mirror connection to an Nch transistor in response to BIAS_I.

A current proportional to a current generated by the DA converter indicates a maximum value of a current to be charged or discharged with respect to a load capacity of an inverter. Since a constant current is charged or discharged with respect to the load capacity, a linear relation between time and voltage is obtained.

When an amount of the current to be generated by the DA converter is changed, the maximum value of the current to be charged or discharged changes, an inclination of a straight line indicating the relation between time and voltage changes, and the delay time changes. The circuit is used as a variable delay circuit by use of the above property.

Differential Delay Element (FIG. 13(b))

Upper resistances are constituted so that a resistance value changes with a combination of Pch transistors in accordance with BIAS_R.

The center Nch transistor functions as an analog switch.

In a lower current source, a current to be charged or discharged with respect to a load capacity is controlled in the same manner as in the single delay element.

Here, a reason why the upper resistances are variable resistances will be described. If the resistances are fixed resistances, an amplitude changes with the current amount of the lower current source. Therefore, a resistance value is controlled so as to change with the current amount.

The delay element group 16 has a plurality of dependently connected delay elements 16-11 to 16-1n (hereinafter referred to simply as the “delay elements 16-1”), and output means are output from stages of the plurality of delay elements 16-1.

In the delay elements 16-1, currents flowing through the delay elements 16-1 are adjusted to vary tr/tf of an output waveform. In consequence, the delay amount is varied.

Specific circuit constitutions of the delay elements 16-1 are shown in FIGS. 13(a), (b). FIG. 13(a) shows the specific circuit constitution of the single delay element, and FIG. 13(b) shows the specific circuit constitution of the differential delay element.

In the single delay element, as shown in FIG. 13(a), a current source is inserted between an inverter element and a power source, and a maximum amount of the current to charge the load capacity connected to an output terminal is changed (limited) to vary tr/tf of the output waveform.

As a result, the delay amount of the delay element changes.

In the differential delay element, as shown in the FIG. 13(b), a differential buffer of a CML type is constituted, a tail current is controlled, and the amount of the current to charge the load capacity connected to the output terminal is changed to thereby vary tr/tf of the output waveform. A variable resistance on a positive power supply side is a variable resistance having a resistance value thereof which is varied in accordance with a change of a tail current amount so that a change of the amplitude does not decrease owing to the variable tail current.

It is a general technique to constitute the variable resistance by use of the Pch transistor.

As described above, the delay lock loop circuit of the present invention includes the delay element group constituted by dependently connecting a plurality of delay elements having the equal delay amount and configured to output the output signals having an equal phase interval from the stages. Therefore, the circuit is usable in the following applications ((1) coarse delay of a timing generator, (2) a local DLL or a local PLL which reduces skew of CLK distribution of LSI, and (3) a multiplier CLK generation circuit and a CLK recovery circuit of a high-speed data transmitter such as SERDES).

The DLL of the present invention having the above constitution produces the following effects.

For example, in a case where it is assumed that two delay time acquiring sections have different resolutions, one of the sections has a coarse resolution and the other section has a fine resolution, the lock range can be extended without increasing the bits of the counter.

Moreover, since the adding section adds up the delay times indicated by the delay time signals output from the delay time acquiring sections, the sum of the delay times can be obtained while both of the delay time of the coarse resolution and the delay time of the fine resolution are reflected. Therefore, the lock-up time can rapidly be shortened as compared with a case where the resolution is simply enlarged.

Furthermore, even upon deviation from the lock range due to influences of an incoming noise and the like, the count value does not stick to a minimum or maximum value, and the delay time can quickly be returned to the lock range.

Examples of a factor for the sticking count value include a fluctuation of the delay amount of the delay circuit (or RING OSC). Examples of a cause for generation of the fluctuation of the delay amount include a temperature fluctuation and a power voltage fluctuation. The temperature fluctuation and the power fluctuation are also generated owing to an incoming fluctuation, or generated in a case where a self operation ratio changes.

When actual temperature and voltage fluctuations are larger than temperature and voltage fluctuations assumed during design, the circuit is to track the fluctuations, and the count value changes to the minimum or maximum value. As a result, the count value sticks to the minimum or maximum value. Conversely, in a case where the actual temperature and voltage fluctuations are smaller than the temperature and voltage fluctuations assumed during the design, when the delay amount is larger than a certain medium value (the count value which is the lock target), the counter counts up so as to reduce the delay amount.

When the feedback control is applied and the delay amount is smaller than the certain medium value (the count value which is the lock target), the feedback control is applied so that the counter counts down so as to increase the delay amount. The counter repeats counting up/down centering on the certain medium value (the count value which is the lock target). At this time, the DLL is brought into a lock state, and the delay amount of the delay circuit of the DLL is large than the amount influenced by the temperature and voltage fluctuations. Therefore, the counter does not overflow (stick).

In addition, the places to be adjusted (calibrated) decrease, and measurement until locking can be reduced.

According to the present invention, the current to be charged or discharged with respect to an inverter of a CMOS is limited to change rising/falling of a passing pulse waveform, and a difference between propagation delay times is used in the delay circuit.

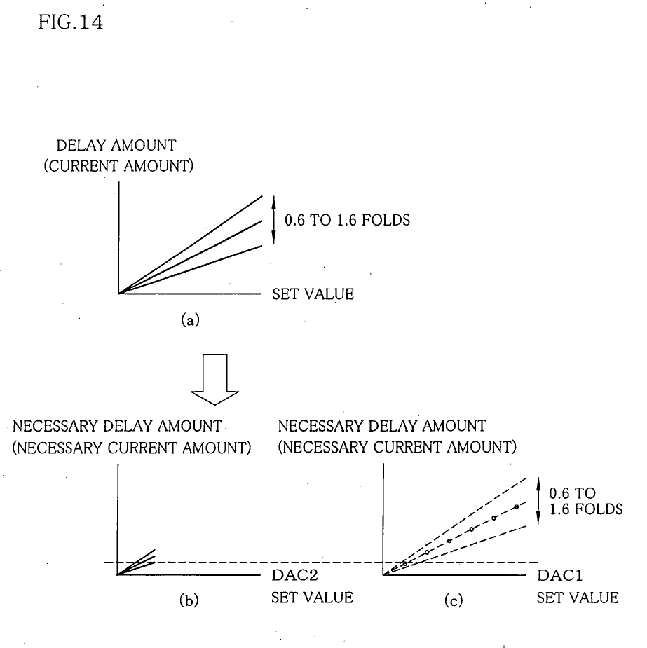

In a process of the CMOS, even in the same circuit, the propagation delay time, the current amount and the like fluctuate in a range of 0.6 to 1.6 folds with respect to a standard device owing to various factors such as reticle and impurity concentration (FIG. 14(a)).

When one DA converter performs a DLL operation as in a conventional example, to absorb the fluctuations, the counter and the DA converter (the DA converter 2) have an enormous number of bits, and the calibration to match the center of an operation point with the vicinity of a portion to be locked is eliminated. Another alternative is considered in which the DA converter (the DA converter 1) having a coarse resolution is disposed in order to avoid the enormous number of the bits, a memory or a register is constituted instead of the phase comparator and the counter of FIG. 1, and the calibration is performed so as to match the center of the operation point with the vicinity of the portion to be locked.

It is to be noted that, when it is presumed that the latter alternative is selected to perform the calibration, a system of the present invention does not require any calibration. Therefore, it is described that “the places to be calibrated are reduced”.

When one type of circuit is realized in this manner, a micro-resolution circuit constituted of multiple bits is required in order to secure necessary resolution and variable amount. On the other hand, when two or more types of circuits having different resolutions are realized (FIGS. 14(b), (c)), a circuit scale decreases.

Moreover, when the DA converter 13a and the DA converter 13b are constituted so as to have the same circuit constitution and the only resolutions (BIAS) are changed, an additional circuit having a small scale can be realized.

Here, the resolution of the DA converter 1 is designed so as to be smaller than the variable amount of the DA converter 2. In this case, the DA converter 13a may be controlled by the memory, the register or the like, but the calibration needs to be performed. However, when the DA converter 13 is also added to the feedback control, circuits of the counter and the phase comparator are increased, but the calibration is not necessary.

Furthermore, even upon the deviation from the lock target due to the influences of the incoming noise and the like, the delay amount can quickly return to a periphery of the lock target.

In addition, any glitch generated in a case where the counter is operated in a binary form is not output, and the circuit is usable even in an application region where the number of emitted pulses is controlled.

The DLL of the first embodiment described above has a delay component having a small resolution and a delay component having a large resolution. Therefore, even upon large deviation from the lock target due to disturbances and the like, the delay amount can quickly come close to the lock target. The DLL of the first embodiment is a very useful technology in that the above effect is produced. However, when, for example, a noise having a large amplitude is tracked, it is assumed that the CTR2 of FIG. 1 overflows (the count value is above a predetermined range) or underflows (the count value is below the predetermined range).

To avoid the overflow and the like, for example, a method of increasing the bits of the CTR2 is considered. However, this method has a demerit that the circuit scale increases.

To solve the problem, a controller circuit which controls operations of a plurality of counters is newly disposed in the DLL, and carrying/borrowing of the delay components having the small and large resolutions are performed. In consequence, the lock range can be broadened without increasing the circuit scale.

Next, the DLL including this controller circuit will be described as a second embodiment.

### Second Embodiment of DLL

Next, a second embodiment of a DLL will be described with reference to FIG. 15.

The drawing is a block diagram showing a constitution of the DLL of the present embodiment.

The DLL of the present embodiment is different from the DLL of the first embodiment in that a new controller circuit for controlling a CTR is disposed. The other constituting elements are similar to those of the DLL of the first embodiment.

As shown in the drawing, a DLL 50 includes phase comparators (PD) 51a, 51b; counters (CTR) 52a, 52b; DA converters (DAC) 53a, 53b; an adder element 54; a BIAS 55; a delay element group 56; and a controller circuit (Controller) 57.

Here, the phase comparator 51a, the counter 52a and the DA converter 53a generate delay having a large (coarse) resolution, and the phase comparator 51b, the counter 52b and the DA converter 53b generate delay having a small (fine) resolution. It is to be noted that a circuit may be constituted so that a delay amount of two bits of the DA converter 53a is equal to a variable amount (a maximum value) of the DA converter 53b, and a calibration result may satisfy the above conditions.

Moreover, a delay time corresponding to a difference between a minimum value of the counter 52b (a first counter) and a half value or a delay time corresponding to a difference between a maximum value of the counter 52b (the first counter) and the half value is equal to a delay time corresponding to one bit of the counter 52a (a second counter).

Moreover, since the DA converters (DAC) 53a, 53b, the adder element 54, the BIAS 55 and the delay element group 56 of the DLL 50 of the present embodiment have functions similar to those of the DA converters (DAC) 13a, 13b, the adder element 14, the BIAS 15 and the delay element group 16 of the DLL 10 of the first embodiment, respectively, detailed description thereof is omitted.

It is to be noted that the DA converter 53a corresponds to a second delay time acquiring section, and the DA converter 53b corresponds to a first delay time acquiring section. The adder element 54 corresponds to an adding section, and the BIAS 55 corresponds to a delay time control section.

The phase comparator (the second phase comparator) 51a may have a constitution shown in FIG. 2, that is, a constitution similar to that of the phase comparator 11a of the DLL 10 of the first embodiment. Moreover, the phase comparator 51a outputs a flag (phase) signal indicating one of UP, DOWN and HOLD (or Toggle).

It is to be noted that in the present embodiment, it is assumed that the signal output from the phase comparator 51a indicates UP, DOWN or Toggle.

This phase comparator 51a inputs an input signal to be input into the delay element group 56 and an output signal to be output from the delay element group 56, respectively, detects a phase between these signals, and outputs the detection result as a phase signal.

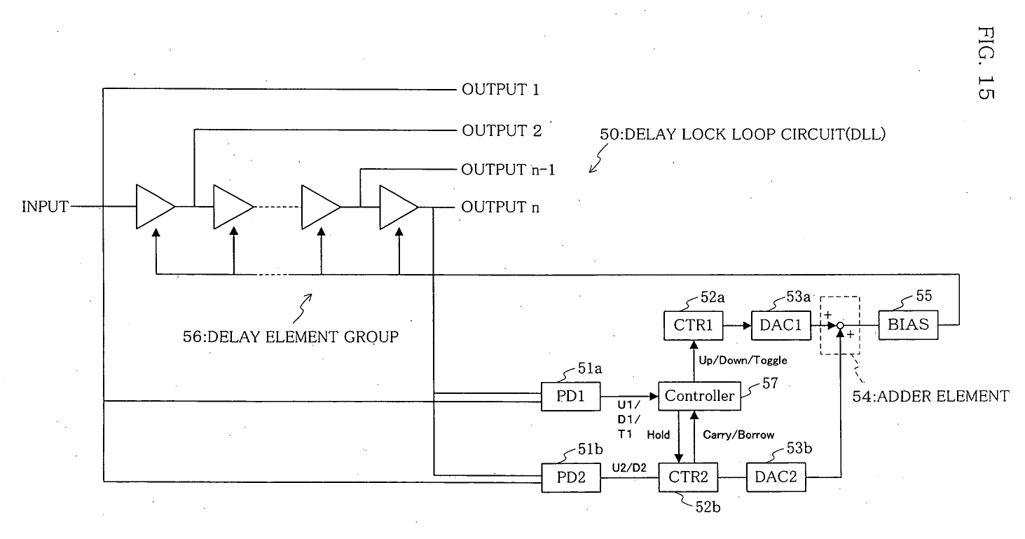

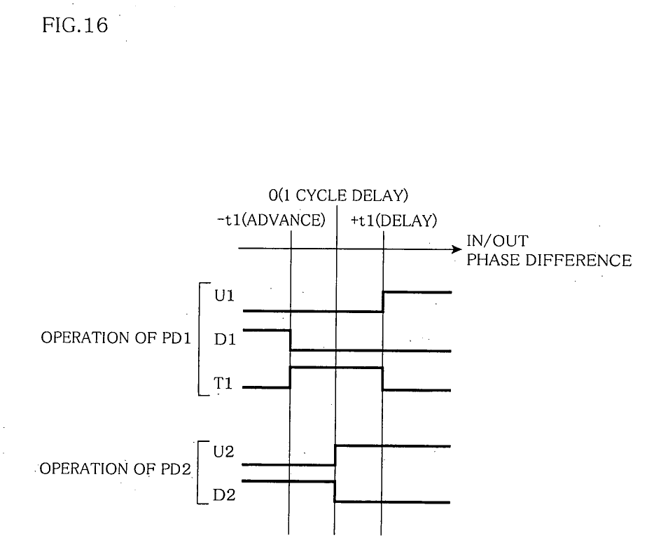

Specifically, an operation shown in an upper stage of FIG. 16 is performed.

That is, in a case where the output signal (OUT) is behind the input signal (IN) as much as +t1 or more from 0 (1 cycle delay), the flag (phase) signal (“U1” in the drawing) indicating UP is output. In a case where the output signal (OUT) is ahead of the input signal (IN) as much as −t1 or more from 0 (1 cycle delay), the flag (phase) signal (“D1” in the drawing) indicating DOWN is output. Furthermore, in a case where there is a phase difference in a range of +t1 to −t1 centering on 0 (1 cycle delay) between the output signal (OUT) and the input signal (IN), the flag (phase) signal (“T1” in the drawing) indicating Toggle is output.

The phase comparator (the first phase comparator) 51b may have a constitution shown in FIG. 5, that is, a constitution similar to that of the phase comparator 11b of the DLL 10 of the first embodiment. Moreover, the phase comparator 51b outputs a flag (phase) signal indicating one of UP and DOWN.

The phase comparator 51b inputs an input signal to be input into the delay element group 56 and an output signal to be output from the delay element group 56, respectively, detects a phase between these signals, and outputs the detection result as a phase signal in the same manner as in the phase comparator 51a.

Specifically, an operation shown in a lower stage of FIG. 16 is performed.

That is, in a case where the output signal (OUT) is behind the input signal (IN) from 0 (1 cycle delay), the flag (phase) signal (“U2” in the drawing) indicating UP is output. On the other hand, in a case where the output signal (OUT) is ahead of the input signal (IN) from 0 (1 cycle delay), the flag (phase) signal (“D2” in the drawing) indicating DOWN is output.

The counter 52a (the second counter) may have a constitution shown in FIG. 9, that is, the same constitution as that of the counter 12a of the DLL 10 of the first embodiment.

This counter 52a inputs a flag signal (UP, DOWN or Toggle) from the controller circuit 57, and outputs a control signal to the DA converter 53a.

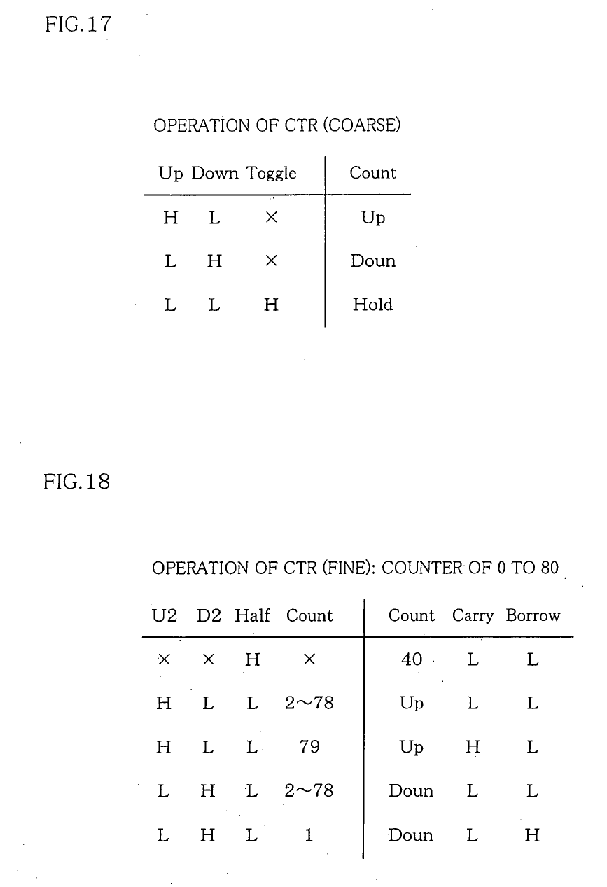

An operation of the counter 52a will be described with reference to FIG. 17. The drawing is a table of true value indicating an operation of the counter 52a.

When the flag signal of UP is input into the counter 52a, a count value increases. When the flag signal of DOWN is input into the counter 52a, the count value decreases. When the flag signal of Toggle is input into the counter 52a, the counter holds.

The counter 52b (the first counter) may have the constitution shown in FIG. 9, that is, the same constitution as that of the counter 12a of the DLL 10 of the first embodiment in the same manner as in the counter 52a.

The counter 52b inputs a flag (phase) signal from the phase comparator 51b and a half signal from controller circuit 57, respectively. The counter 52b outputs a digit shift signal (Carry, Borrow) to the controller circuit 57 and a control signal to the DA converter 53b, respectively.

It is to be noted that an output terminal of the digit shift signal (Carry, Borrow) may be disposed as follows.

For example, in a counter of 40 bits, that is, in a case where the counter is constituted of 40 MUXs and 40 D-FFs of FIG. 9, a borrow signal (Borrow) may be a negative output of a first bit (a first stage) of the D-FF, and a carry signal (Carry) may be a positive output of a 39-th bit (a 39-th stage) of the D-FF.

An operation of this counter 52b will be described with reference to FIG. 18. The drawing is a table of true value indicating the operation of the counter 52b.

It is to be noted that the delay time corresponding to the difference between the minimum value of the counter 52b (the first counter) and the half value or the delay time corresponding to the difference between the maximum value of the counter 52b (the first counter) and the half value is equal to the delay time corresponding to one bit of the counter 52a (the second counter).

When the flag (phase) signal of UP is input into the counter 52b from the phase comparator 51b, a count value increases. Here, when the count value is 2 to 78 (a predetermined range of the counter of 0 to 80), any digit shift signal (the carry signal (Carry), the borrow signal (Borrow)) is not output. On the other hand, when the count value is 79 (above the predetermined range), the carry signal (Carry) is output and sent to the controller circuit 57. It is to be noted that in this case, any borrow signal (Borrow) is not output.

On the other hand, when the flag (phase) signal of DOWN is input into the counter 52b from the phase comparator 51b, the count value decreases. Here, when the count value is 2 to 78, any digit shift signal is not output. On the other hand, when the count value is 1 (below the predetermined range), the borrow signal (Borrow) is output and sent to the controller circuit 57. It is to be noted that in this case, any carry signal (Carry) is not output.

Moreover, when a flag signal of Half is input into the counter 52b from the controller circuit 57, the count value is set to a half value (halved).

Here, an operation in a case where the count value of the counter 52b is set to the half value is performed as follows.

For example, when the MUXs and D-FFs shown in FIG. 9 include 40 stages, the D-FFs of the first to 20-th stages are set to “H”, and the D-FFs of the 21-st to 40-th stages are set to “L”.

As realizing means, the D-FFs of the first to 20-th stages include preset terminals, the D-FFs of the 21-st to 40-th stages include clear terminals, and signals for setting the half value may be connected to these preset and clear terminals to realize the constitution.

The controller circuit 57 is a circuit block which controls operations of two counters 52a, 52b, and inputs the flag (phase) signal (UP, DOWN or Toggle) from the phase comparator 51a and the digit shift signal (Carry, Borrow) from the counter 52b, respectively. The controller circuit 57 sends the half signal to the counter 52b and the flag signal (UP, DOWN or Toggle) to the counter 52a, respectively.

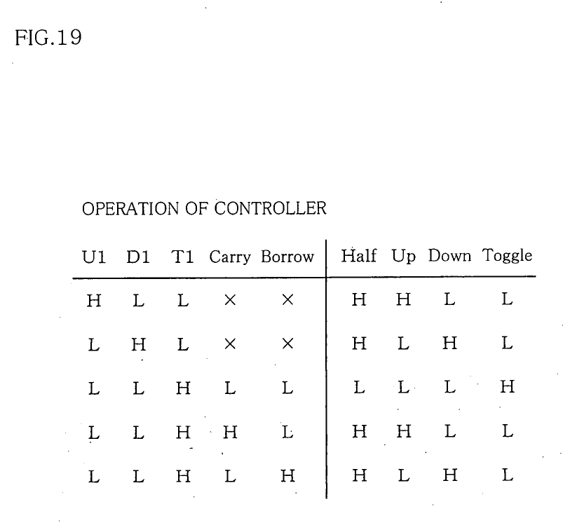

An operation of the controller circuit 57 will be described with reference to FIG. 19.

For example, when the flag (phase) signal of UP is input from the phase comparator 51a, the controller circuit 57 outputs a flag signal of UP to the counter 52a, and outputs a flag signal of Half to the counter 52b.

Moreover, when the flag (phase) signal of DOWN is input from the phase comparator 51a, the controller circuit 57 outputs a flag signal of DOWN to the counter 52a, and outputs the flag signal of Half to the counter 52b.

On the other hand, when the flag (phase) signal of Toggle is input from the phase comparator 51a, the operation differs depending on whether or not the carry signal (Carry) or the borrow signal (Borrow) is input from the controller circuit 57.

When the flag (phase) signal of Toggle is input and any of the carry signal (Carry) and the borrow signal (Borrow) is not input, the flag signal of Toggle is output to the counter 52a. In this case, the signals of Half, UP and DOWN are not output.

Moreover, when the flag (phase) signal of Toggle is input and the carry signal (Carry) is also input, the flag signal of UP is output to the counter 52a. Moreover, the flag signal of Half is output to the counter 52b.

Furthermore, when the flag (phase) signal of Toggle is input and the borrow signal (Borrow) is also input, the flag signal of DOWN is output to the counter 52a. Moreover, the flag signal of Half is output to the counter 52b.

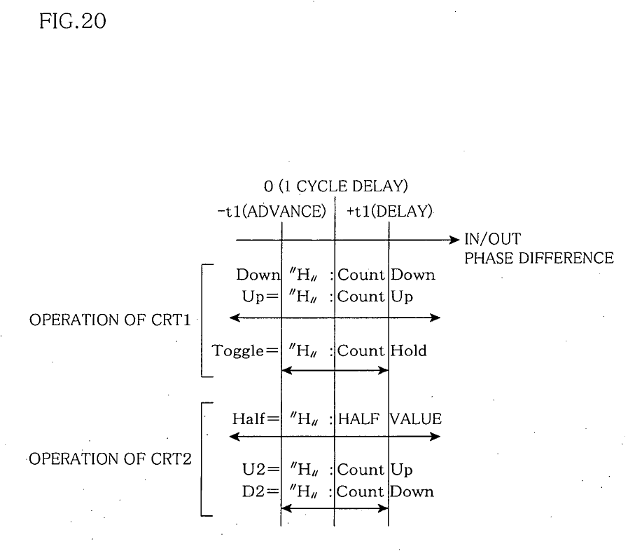

Next, a phase difference (an IN/OUT phase difference) between the input signal and the output signal and an operation of the DLL based on this difference will be described with reference to FIG. 20.

An upper stage of the drawing is a drawing showing a relation between the IN/OUT phase difference and the operation of the counter 52a, and a lower stage of the drawing is a drawing showing a relation between the IN/OUT phase difference and the operation of the counter 52b.

First, a case where the output signal (OUT) is behind the input signal (IN) as much as +t1 or more from 0 (1 cycle delay) will be described.

In this case, the phase comparator 51a outputs a flag (phase) signal of UP (U1), and the phase comparator 51b outputs a flag (phase) signal of UP (U2).

On receiving the flag (phase) signal of UP (U2) from the phase comparator 51b, the counter 52b counts up (“U2 “H”: Count Up” of a lower stage of FIG. 20). Here, when the count value is 2 to 78, any digit shift signal is not output. On the other hand, when the count value is 79, the carry signal (Carry) is output to the controller circuit 57.

On receiving the flag (phase) signal of UP (U1) from the phase comparator 51a, the controller circuit 57 outputs the flag signal of UP to the counter 52a, and outputs the half signal to the counter 52b.

On receiving the flag signal of UP from the controller circuit 57, the counter 52a counts up (“Up=“H”: Count Up” of an upper stage of FIG. 20).

On receiving the half signal from the controller circuit 57, the count value of the counter 52b is set to the half value (“Half=“H”: half value” of the lower stage of FIG. 20).

It is to be noted that the controller circuit 57 receives the carry signal (Carry) from the counter 52b, but the signal from the phase comparator 51a does not indicate Toggle. Therefore, an operation in response to the received carry signal (Carry) is not performed.

Next, a case where the output signal (OUT) is ahead of the input signal (IN) as much as −t1 or more from 0 (1 cycle delay) will be described.

In this case, the phase comparator 51a outputs a flag (phase) signal of DOWN (D1), and the phase comparator 51b outputs a flag (phase) signal of DOWN (D2).

On receiving the flag (phase) signal of DOWN (D2) from the phase comparator 51b, the counter 52b counts down (“D2=“H”: Count Down” of the lower stage of FIG. 20). Here, when the count value is 2 to 78, any digit shift signal is not output. On the other hand, when the count value is 1, the borrow signal (Borrow) is output to the controller circuit 57.

On receiving the flag (phase) signal of DOWN (D1) from the phase comparator 51a, the controller circuit 57 outputs the flag signal of DOWN to the counter 52a, and outputs the half signal to the counter 52b.

On receiving the flag signal of DOWN from the controller circuit 57, the counter 52a counts down (“Down=“H”: Count Down” of the upper stage of FIG. 20).

On receiving the half signal from the controller circuit 57, the count value of the counter 52b is set to the half value (“Half=“H”: half value” of the lower stage of FIG. 20).

It is to be noted that the controller circuit 57 receives the borrow signal (Borrow) from the counter 52b, but the signal from the phase comparator 51a does not indicate Toggle. Therefore, an operation in response to the received borrow signal (Borrow) is not performed.

Next, a case where the phase difference between the output signal (OUT) and the input signal (IN) is in a range of 0 (1 cycle delay) to +t1 (delay) will be described.

In this case, the phase comparator 51a outputs a flag (phase) signal of Toggle (T1), and the phase comparator 51b outputs a flag (phase) signal of UP (U2).

On receiving the flag (phase) signal of UP (U2) from the phase comparator 51b, the counter 52b counts up (“U2=“H”: Count Up” of the lower stage of FIG. 20). Here, when the count value is 2 to 78, any digit shift signal is not output. On the other hand, when the count value is 79, the carry signal (Carry) is output to the controller circuit 57.

The controller circuit 57 receives the flag (phase) signal of Toggle (T1) from the phase comparator 51a. In this case, the operation differs, depending on whether or not the carry signal (Carry) or the borrow signal (Borrow) is input from the counter 52b.

When the carry signal (Carry) or the borrow signal (Borrow) is not input (i.e., when the count value of the counter 52b is 2 to 78), the flag signal of Toggle is output to the counter 52a. In this case, any half signal is not output to the counter 52b. Moreover, the counter 52a receives the flag signal of Toggle, and does not count up or down (“Toggle=“H”: Count Hold” of the upper stage of FIG. 20).

On the other hand, when the carry signal (Carry) is input (i.e., when the count value of the counter 52b is 79), the flag signal of UP is output to the counter 52a, and the flag signal of Half is output to the counter 52b. In consequence, the counter 52a receives the flag signal of UP, and counts up (“Up “H”: Count Up” of the upper stage of FIG. 20). On the other hand, the counter 52b receives the flag signal of Half, and the count value of the counter is set to the half value (“Half=“H”: half value” of the lower stage of FIG. 20).

It is to be noted that the borrow signal (Borrow) is output in a case where the count value of the counter 52b turns to 1. This signal is output in a case where the flag (phase) signal of DOWN is output from the phase comparator 51a, that is, in a case where the output signal (OUT) is ahead of the input signal (IN) as much as a phase difference in excess of 0 (1 cycle delay) or more. Therefore, the output of the borrow signal is not assumed here.

Next, a case where the phase difference between the output signal (OUT) and the input signal (IN) is in a range of 0 (1 cycle delay) to −t1 (advance) will be described.

In this case, the phase comparator 51a outputs the flag (phase) signal of Toggle (T1), and the phase comparator 51b outputs the flag (phase) signal of DOWN (D2).

On receiving the flag (phase) signal of DOWN (D2) from the phase comparator 51b, the counter 52b counts down (“D2=“H”: Count Down” of the lower stage of FIG. 20). Here, when the count value is 2 to 78, any digit shift signal is not output. On the other hand, when the count value is 1, the borrow signal (Borrow) is output to the controller circuit 57.

The controller circuit 57 receives the flag (phase) signal of Toggle (T1) from the phase comparator 51a. In this case, the operation differs, depending on whether or not the carry signal (Carry) or the borrow signal (Borrow) is input.

When the carry signal (Carry) or the borrow signal (Borrow) is not input (i.e., when the count value of the counter 52b is 2 to 78), the flag signal of Toggle is output to the counter 52a. In this case, any half signal is not output to the counter 52b. Moreover, the counter 52a receives the flag signal of Toggle, and does not count up or down (“Toggle=“H”: Count Hold” of the upper stage of FIG. 20).

On the other hand, when the borrow signal (Borrow) is input (i.e., when the count value of the counter 52b is 1), the flag signal of DOWN is output to the counter 52a, and the flag signal of Half is output to the counter 52b. In consequence, the counter 52a receives the flag signal of DOWN, and counts down (“Down=“H”: Count Down” of the upper stage of FIG. 20). On the other hand, the counter 52b receives the flag signal of Half, and the count value of the counter is set to the half value (“Half=“H”: half value” of the lower stage of FIG. 20).

It is to be noted that the carry signal (Carry) is output in a case where the count value of the counter 52b turns to 79. This signal is output in a case where the flag (phase) signal of UP is output from the phase comparator 51a, that is, in a case where the output signal (OUT) is behind the input signal (IN) as much as a phase difference in excess of 0 (1 cycle delay). Therefore, the output of the carry signal is not assumed here.

As described above, in the DLL of the present embodiment, when the IN/OUT phase difference is around 0 (in actual, the phase difference between IN and OUT is a state of just 1 cycle delay), in accordance with the results of the phase comparators 51a, 51b and the control of the controller circuit 57, the counter 52b counts up or down, the counter 52a holds the count value, and the only delay having the small resolution is tracked. On the other hand, when the IN/OUT phase difference is out of a desired phase difference range (externally from ft in FIG. 16), in accordance with the results of the phase comparators 51a, 51b and the control of the controller circuit 57, the count value of the counter 52a is fixed to the half value, the counter 52a counts up or down, and the only delay having the large resolution is tracked.

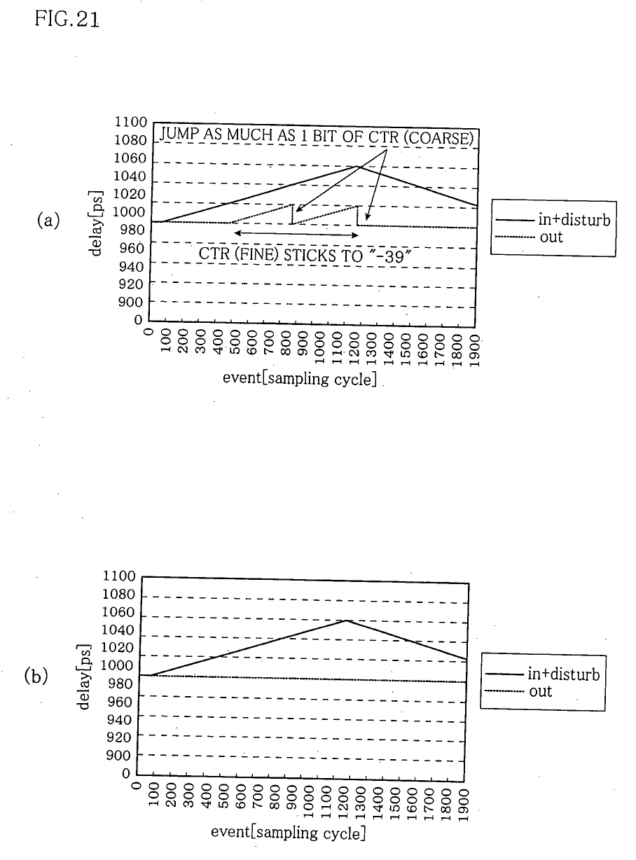

Next, a simulation result of the DLL of the present embodiment in comparison with that of a conventional DLL will be described with reference to FIGS. 21(a), (b).

FIG. 21(a) is a graph showing the simulation result of the conventional DLL, and FIG. 21(b) is a graph showing the simulation result of the DLL of the present embodiment.

Moreover, in FIGS. 21(a), (b), a solid line indicates an input signal (in) mixed with disturbances (disturb, noise), and a broken line indicates an output signal (out).

It is to be noted that FIGS. 21(a), (b) show the results of the simulation of a case where a waveform of the disturbance having a low frequency and a large amplitude, especially a frequency component of the disturbance has a (frequency) band lower than that of the DLL, and an amplitude larger than a bit width of the counter 52b (having the smaller resolution) (an environment where the DLL is mounted, fluctuations of power voltage and temperature have a low frequency and a large amplitude).

In the conventional DLL, as shown in FIG. 21(a), with the generation of the disturbance, the counter 52b (CTR (fine)) “sticks to” “−39”. Moreover, “jump” as much as 1 bit occurs in the counter 52a (CTR (coarse)).

On the other hand, in the DLL of the present embodiment, as shown in FIG. 21(b), although the disturbance is generated in the input signal, the counter 52b (CTR (fine)) avoids the “sticking state”, and any “jump” does not occur in the counter 52a (CTR (coarse)). That is, the lock range is improved.

A reason why the “sticking state” is avoided and any “jump” does not occur as shown in FIG. 21(b) is that the DLL is provided with a new controller circuit so that the operations of two counters can be controlled. When the count value of the counter 52b is above (“79” in the drawing) or below (“1” in the drawing) a predetermined range (“2 to 78” of FIG. 18), the carrying/borrowing of the delay components having the small and large resolutions are performed. In consequence, the lock range can be broadened without increasing the circuit scale of the counter, and the overflow or the underflow can be avoided in the counter.

[PLL]

### First Embodiment of PLL

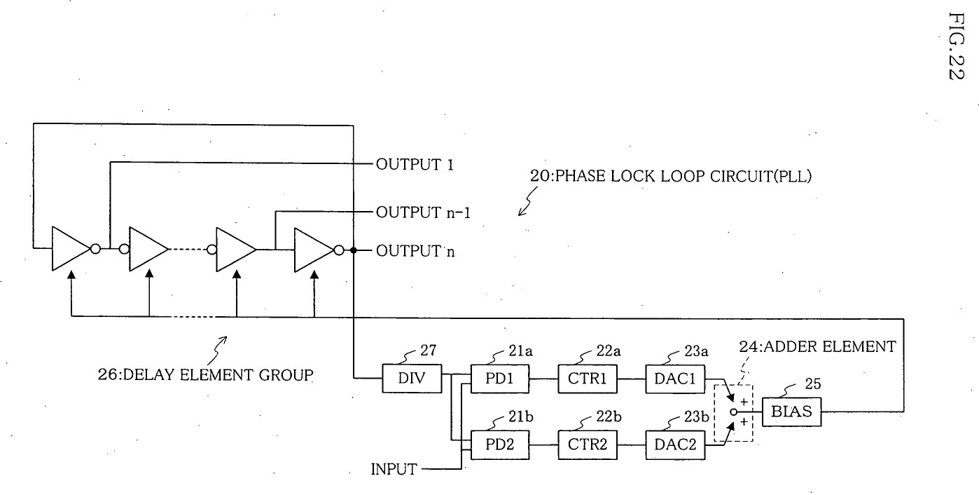

Next, a PLL of the present embodiment will be described with reference to FIG. 22.

As shown in the drawing, a PLL 20 includes phase comparators (PD) 21a, 21b; counters (CTR) 22a, 22b; DA converters (DAC) 23a, 23b; an adder element 24; a BIAS 25; a delay element group 26; and a frequency demultiplier (a divider: DIV) 27.

The phase comparators 21a, 21b have functions similar to those of the phase comparators 11a, 11b of the DLL 10 of the present invention described above.

Moreover, the counters 22a, 22b have functions similar to those of the counters 12a, 12b of the DLL 10, the DA converters 23a, 23b have functions similar to those of the DA converters 13a, 13b of the DLL 10, the adder element 24 has a function similar to that of the adder element 14 of the DLL 10, the BIAS 25 has a function similar to that of the BIAS 15 of the DLL 10, and the delay element group 26 has a function similar to that of the delay element group 16 of the DLL 10.

Moreover, the PLL 20 of the present embodiment can be realized, when a constitution is changed by replacing DELAY (including the DA converters 13a, 13b, the adder element 14, the BIAS 15 and the delay element group 16) of the DLL 10 of the present invention described above with a ring oscillator (RING OCS: including the DA converters 23a, 23b, the adder element 24, the BIAS 25 and the delay element group 26); further disposing the divider 27; inputting input signals into the phase comparators 21a, 21b from the outside and the like.

When the PLL is constituted as described above, a lock-up time can largely be reduced. In addition, a lock range can be extended.

### Second Embodiment of PLL

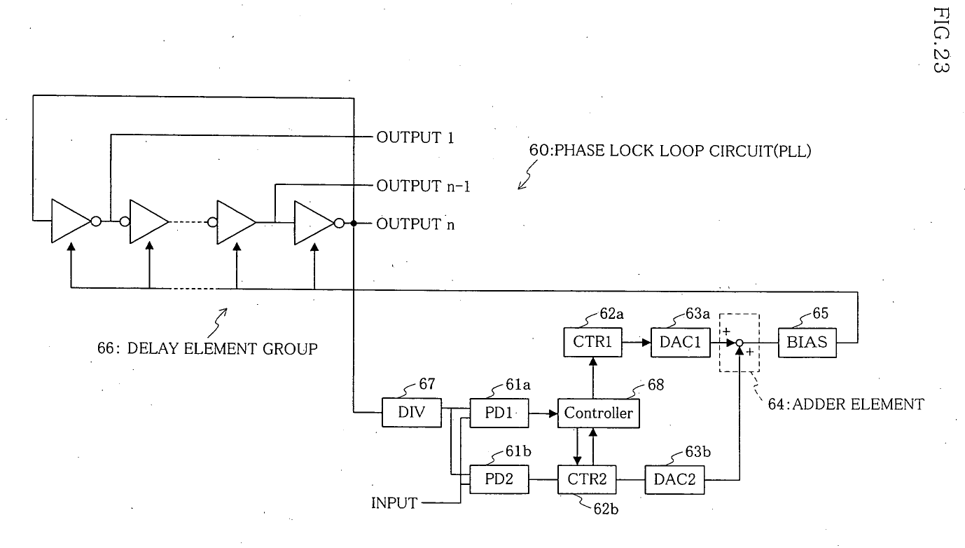

Next, a PLL of the present embodiment will be described with reference to FIG. 23.

The PLL of the present embodiment is different from the PLL of the first embodiment in that a new controller circuit is disposed. The other constitution is similar to that of the PLL of the first embodiment.

As shown in the drawing, a PLL 60 includes phase comparators (PD) 61a, 61b; counters (CTR) 62a, 62b; DA converters (DAC) 63a, 63b; an adder element 64; a BIAS 65; a delay element group 66; a frequency demultiplier (a divider: DIV) 67; and a controller circuit 68.

The controller circuit 68 is a circuit block which controls operations of two counters 62a, 62b in the same manner as in the controller circuit 57 of the DLL 50 of the first embodiment.

This controller circuit 68 has a function similar to that of the controller circuit 57 of the DLL 50 of the second embodiment. The phase comparators 61a, 61b have functions similar to those of the phase comparators 51a, 51b of the DLL 50, and the counters 62a, 62b have functions similar to those of the counters 52a, 52b of the DLL 50.

Furthermore, the DA converters 63a, 63b have functions similar to those of the DA converters 13a, 13b of the DLL 10, the adder element 64 has a function similar to that of the adder element 14 of the DLL 10, the BIAS 65 has a function similar to that of the BIAS 15 of the DLL 10, and the delay element group 66 has a function similar to that of the delay element group 16 of the DLL 10.

Moreover, the PLL 60 of the present embodiment can be realized, when a constitution is changed by replacing DELAY of the present invention described above with a ring oscillator; further disposing the divider 67; inputting input signals into the phase comparators 61a, 61b from the outside and the like.

When the PLL is constituted as described above, a lock-up time can largely be reduced. In addition, a lock range can be extended.

Furthermore, since the controller circuit 68 capable of controlling operations of two counters is disposed in the PLL, carrying/borrowing of delay components having small and large resolutions can be performed. In consequence, the lock range can be broadened without increasing circuit scales of the counters, and overflow and underflow can be avoided in the counters.

[Timing Generator and Semiconductor Tester]

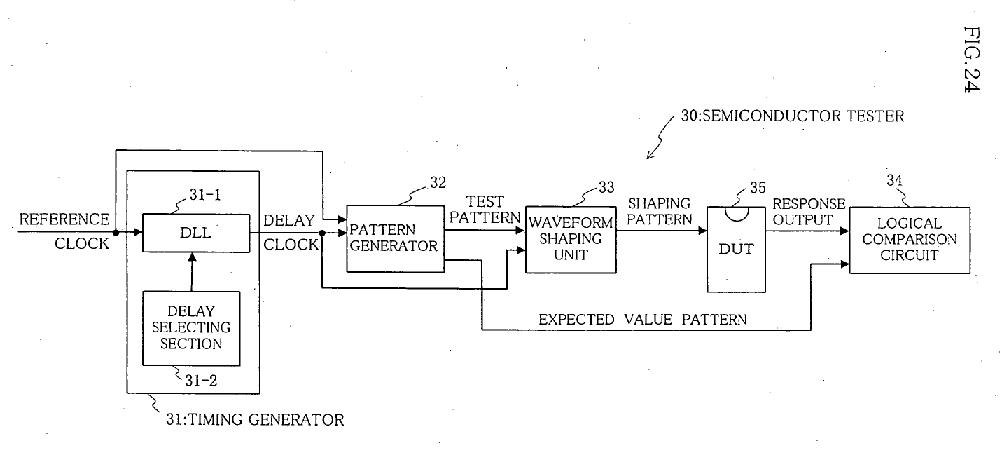

Next, a timing generator of the present embodiment and a semiconductor tester including the timing generator will be described with reference to FIG. 24.

As shown in the drawing, a semiconductor tester 30 of the present embodiment includes a timing generator 31, a pattern generator 32, a waveform shaping unit 33 and a logical comparison circuit 34.

The timing generator 31 outputs a delay clock signal obtained by delaying a reference clock signal for a predetermined time. The pattern generator 32 outputs a test pattern signal in synchronization with the reference clock signal. The waveform shaping unit 33 shapes the test pattern signal in accordance with a device under test (DUT) 35 to send the signal to the DUT 35. The logical comparison circuit 34 compares a response output signal of the DUT 35 with an expected value data signal.

Here, the timing generator 31 includes a delay lock loop circuit (DLL) 31-1 and a delay selecting section 31-2.

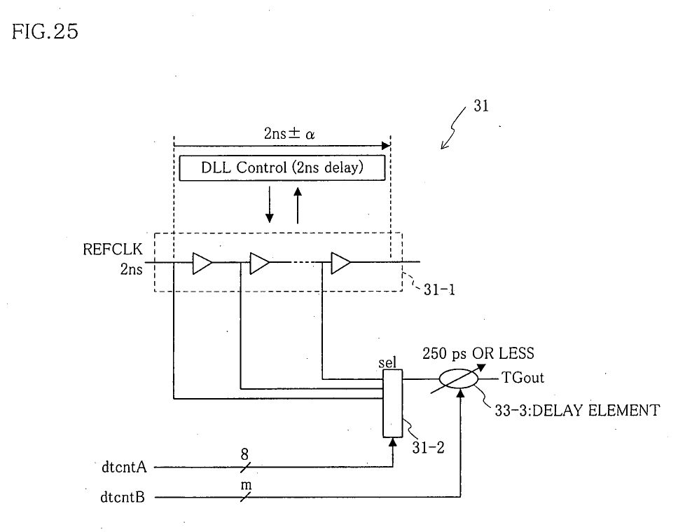

A specific circuit constitution of this timing generator 31 is shown in FIG. 25.

As shown in the drawing, the DLL 31-1 of the timing generator 31 has the DLL (the DLL 10 shown in FIG. 1 or the DLL 50 shown in FIG. 15) of the present invention described above, and includes a variable delay circuit constituted by connecting a plurality of stages of logical gates in series. In addition, the input signal of FIG. 1 corresponds to the reference clock signal of the present embodiment.

The delay selecting section 31-2 selects an output of a certain inverter to output a delay signal. Furthermore, in the example shown in FIG. 25, the timing generator includes a delay element 31-3 which generates a delay time of 250 ps or less.

Since the timing generator is constituted in this manner, precision of a delay amount to be applied to the delay clock signal can be improved.

Moreover, since the semiconductor tester includes the timing generator of the present invention, timings of sections of a device are achieved in response to the delay clock signal to which the highly precise delay amount has been applied. Therefore, measurement precision of a semiconductor test can be improved.

It is to be noted that in the present embodiment, the constitution of the timing generator including the DLL of the present invention has been described, but the timing generator may include the PLL of the present invention instead of the DLL. Even in this case, the precision of the delay amount to be applied to the delay clock signal can be improved in the same manner as in the timing generator including the DLL.

[Semiconductor Integrated Circuit]

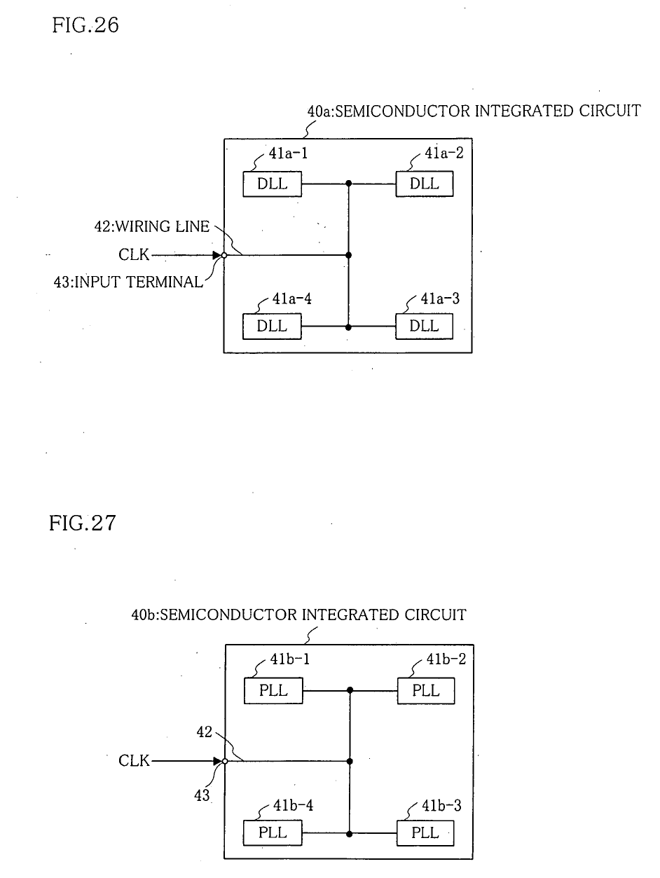

Next, a semiconductor integrated circuit of the present embodiment will be described with reference to FIG. 26.

As shown in the drawing, a semiconductor integrated circuit 40a of the present embodiment includes, for example, four phase lock loop circuits (PLLs) 41a-1 to 41d-4 and a wiring line 42 which distributes reference clock signals having a low frequency to the PLLs 41a-1 to 41d-4.

Each of the PLLs 41a-1 to 41d-4 has the same constitution as that of the PLL (the PLL 20 shown in FIG. 22 or the PLL 60 shown in FIG. 23) of the present invention described above.

Moreover, the reference clock signals having a small skew and a low frequency are input as input signals into the PLLs 41a to 41d, and the PLLs 41a to 41d can self-oscillate each operation clock having a high frequency. As a result, a relay buffer of a clock signal is unnecessary, the skew of the clock signal can be reduced, and designing can be facilitated.

Furthermore, the skews of the reference clock signals are actually generated mainly by a transmission time of the wiring line 42 from an input terminal 43 of a reference clock to each of the PLLs 41a to 41d. Therefore, in the present embodiment, a length of the wiring line from the wiring line 42 of the reference clock to each of the PLLs 41a to 41d is increased.

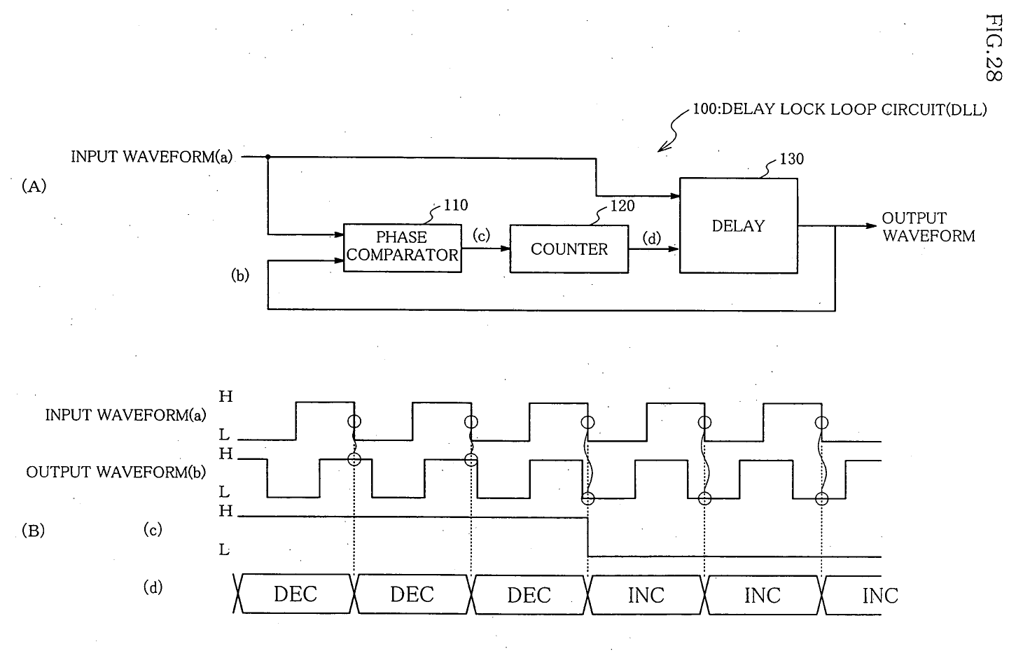

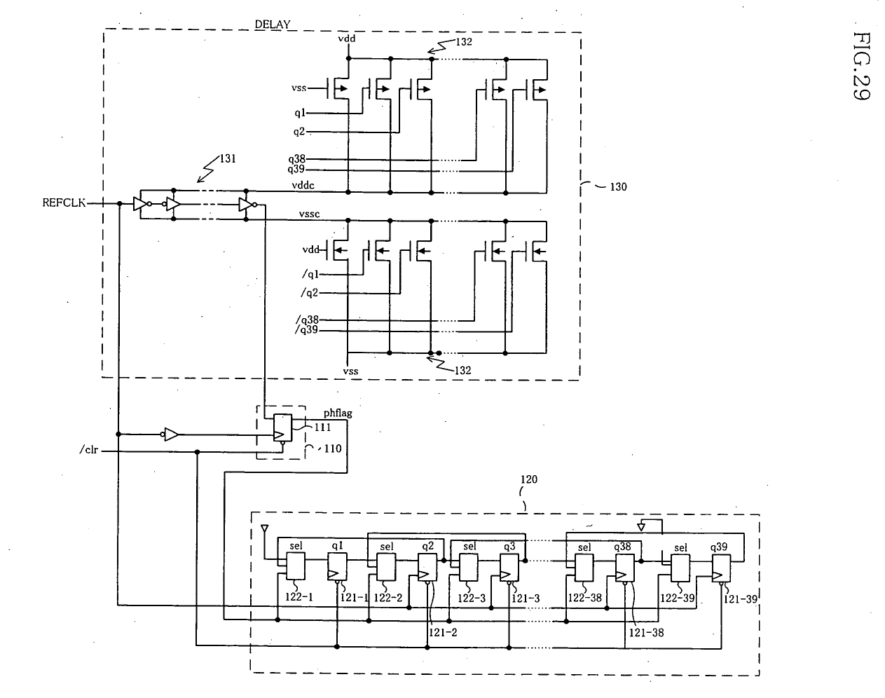

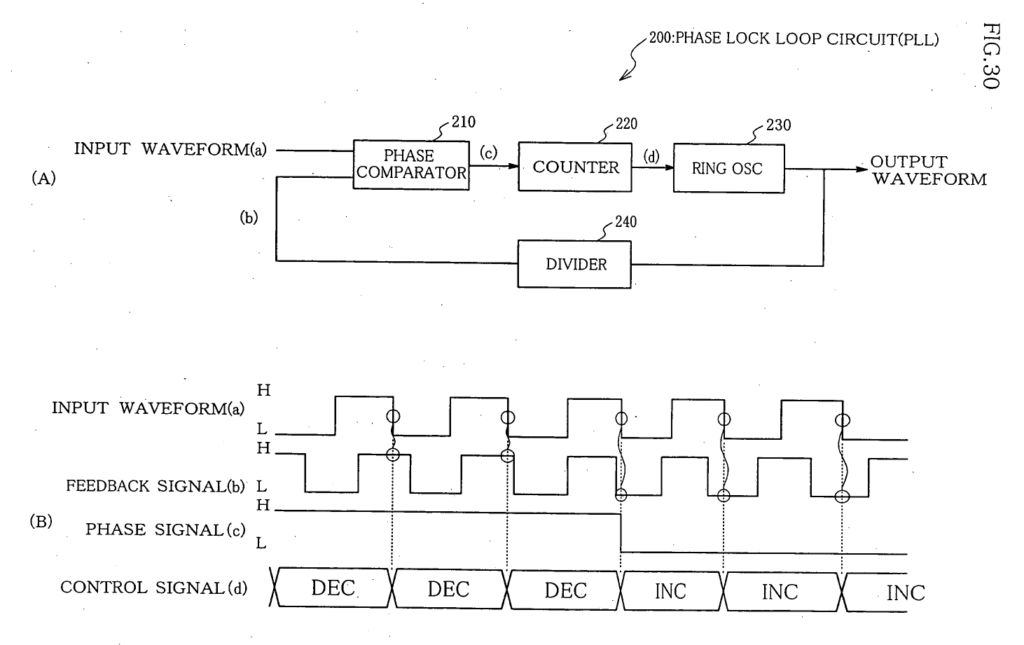

It is to be noted that as shown in FIG. 27, instead of the PLLs 41a-1 to 41d-4, DLLs 41b-1 to 41b-4 of the present invention described above may be arranged in a semiconductor integrated circuit 40b.

When the semiconductor integrated circuit is constituted in this manner, transmission of the CLK at a long distance is performed at a low frequency, and multiplication is performed using the PLL at a local portion. Therefore, a circuit scale and power consumption of a transmitting portion can be reduced. In addition, an only small number of stages of buffers are entirely required. Therefore, the skews can be reduced.

The preferable embodiments of the delay lock loop circuit, the phase lock loop circuit, the timing generator, the semiconductor tester and the semiconductor integrated circuit according to the present invention have been described above, but the delay lock loop circuit, the phase lock loop circuit, the timing generator, the semiconductor tester and the semiconductor integrated circuit according to the present invention are not limited to the only above embodiments. Needless to say, the present invention can variously be modified within the scope of the present invention.

For example, in the above embodiments, an example in which the ring oscillator and the variable delay circuit are constituted by connecting multiple stages of inverters has been described. However, the logical gates of reverse outputs are not limited to the inverters. For example, multiple stages of NAND circuits, NOR circuits and the like may be connected.

### INDUSTRIAL APPLICABILITY

Since the present invention is directed to inventions of a delay lock loop circuit and a phase lock loop circuit for purposes of reduction of a lock-up time and the like, the present invention is usable in a device and an apparatus in which the delay lock loop circuit and the delay lock loop circuit are used.

1. A delay lock loop circuit including a delay element group constituted by dependently connecting a plurality of delay elements having an equal delay amount and configured to output an output signal from each stage of the plurality of delay elements, the circuit comprising:
a plurality of phase comparators which input an input signal and an output signal and which output a phase signal;
a plurality of counters which input the phase signal from the corresponding phase comparator and which output a control signal;
a plurality of delay time acquiring sections which input the control signal from the corresponding counter and which output a delay time signal indicating a delay time corresponding to a bit value of this input control signal;
an adding section which adds up the delay times indicated by the delay time signals output from the plurality of delay time acquiring sections, respectively; and
a delay time control section which converts a sum of the delay times added up by this adding section into the delay time of each delay element of the delay element group,
wherein the plurality of delay time acquiring sections are configured to convert a resolution per unit bit concerning the delay time corresponding to the bit value of the control signal into a different resolution.

2. The delay lock loop circuit according to claim 1, wherein:
the plurality of phase comparators include first and second phase comparators;
the first phase comparator outputs the phase signal indicating one of UP and DOWN based on delay or advance of a phase of the output signal with respect to the input signal; and
the second phase comparator outputs the phase signal indicating one of UP, DOWN and HOLD based on delay, advance or equality of the phase of the output signal with respect to the input signal.

3. The delay lock loop circuit according to claim 1, wherein the phase comparator has an automatic calibration circuit which automatically calibrates skews of the input signal and the output signal.

4. The delay lock loop circuit according to claim 3, wherein the phase comparator has:
a first selector circuit which inputs an input signal and an output signal and which selects the input signal in response to input of a calibration signal into a mode terminal and which outputs this selected input signal as a first selection signal;
a second selector circuit which inputs an input signal and which outputs this input signal as a second selection signal;
a deskew circuit which delays the second selection signal output from this second selector circuit;
a data retaining circuit which outputs the phase signal indicating UP or DOWN based on delay or advance of a phase of the first selection signal with respect to the second selection signal; and
the automatic calibration circuit; wherein the automatic calibration circuit has:
a counter which counts up only when the phase signal indicating UP is received from the data retaining circuit to output a count signal; and
the deskew circuit delays:
the second selection signal based on the count signal output from the counter.

5. The delay lock loop circuit according to claim 1, further comprising:
a voltage generator which applies different current amounts to the plurality of delay time acquiring sections, respectively, to set the resolution per unit bit of each of the delay time acquiring sections to a different value.

6. The delay lock loop circuit according to claim 5, wherein:
a delay time of a high-order resolution is applied to an output signal by use of a first phase comparator which outputs a phase signal indicating one of UP, DOWN and HOLD, a first counter which receives the phase signal from this first phase comparator and a first delay time acquiring section in which the voltage generator determines the resolution per unit bit in accordance with a comparatively long delay time; and
a delay time of a low-order resolution is applied to an output signal by use of a second phase comparator which outputs a phase signal indicating one of UP and DOWN, a second counter which receives the phase signal from this second phase comparator and a second delay time acquiring section in which the voltage generator determines the resolution per unit bit in accordance with a comparatively short delay time.

7. The delay lock loop circuit according to claim 1, wherein the adding section is connected to current paths indicating the delay time signals output from the plurality of delay time acquiring sections via wired OR, and sends, to the delay time control section, a sum of currents as the delay time added up.

8. The delay lock loop circuit according to claim 1:
wherein the delay time control section has a first transistor through which a current indicating the delay time added up by the adding section flows and a second transistor which is a delay element; and
wherein the first transistor is current-mirror connected to the second transistor.

9. The delay lock loop circuit according to claim 1, wherein the first delay time acquiring section has a small resolution, and the second delay time acquiring section has a large resolution;
the delay lock loop circuit further comprising:
a controller circuit which sends a signal to set a count value to a half value to the first counter and sends a signal to count up or down to the second counter based on the phase signal input from the second phase comparator and/or a digit shift signal input from the first counter,
wherein the first counter is configured to send the digit shift signal to the controller circuit, when the first counter counts up or down based on the phase signal from the first phase comparator and the count value is above or below a predetermined range.

10. The delay lock loop circuit according to claim 9, wherein:
the first counter sends a carry digit shift signal to the controller circuit, when the first counter counts up based on the phase signal input from the first phase comparator and indicating UP and the count value is above the predetermined range;
the controller circuit sends a half signal to the first counter to set the count value to the half value and sends the signal indicating UP to the second counter to count up, when receiving the carry digit shift signal and receiving the phase signal indicating HOLD from the second phase comparator;
the first counter sets the count value to the half value when receiving the half signal; and
the second counter counts up when receiving the signal indicating UP.

11. The delay lock loop circuit according to claim 9, wherein:
the first counter sends a borrow digit shift signal to the controller circuit, when the first counter counts down based on the phase signal input from the first phase comparator and indicating DOWN and the count value is below the predetermined range;
the controller circuit sends the half signal to the first counter to set the count value to the half value and sends the signal indicating DOWN to the second counter to count down, when receiving the borrow digit shift signal and receiving the phase signal indicating HOLD from the second phase comparator;
the first counter sets the count value to the half value when receiving the half signal; and
the second counter counts down when receiving the signal indicating DOWN.

12. The delay lock loop circuit according to claim 9, wherein:
the controller circuit sends the half signal to the first counter and sends the signal indicating UP to the second counter, when the phase signal indicating UP is input from the second phase comparator;
the first counter sets the count value to the half value when receiving the half signal; and
the second counter counts up when receiving the signal indicating UP.

13. The delay lock loop circuit according claim 9, wherein:
the controller circuit sends the half signal to the first counter and sends the signal indicating DOWN to the second counter, when the phase signal indicating DOWN is input from the second phase comparator;
the first counter sets the count value to the half value when receiving the half signal; and
the second counter counts down when receiving the signal indicating DOWN.

14. A phase lock loop including a delay element group constituted by dependently connecting a plurality of delay elements having an equal delay amount and configured to output an output signal from each stage of the plurality of delay elements, the circuit comprising:
a plurality of phase comparators which input an input signal and an output signal and which output a phase signal;
a plurality of counters which input the phase signal from the corresponding phase comparator and which output a control signal;
a plurality of delay time acquiring sections which input the control signal from the corresponding counter and which output a delay time signal indicating a delay time corresponding to a bit value of this input control signal;
an adding section which adds up the delay times indicated by the delay time signals output from the plurality of delay time acquiring sections, respectively; and
a delay time control section which converts a sum of the delay times added up by this adding section into the delay time of each delay element of the delay element group,
wherein the plurality of delay time acquiring sections are configured to convert a resolution per unit bit concerning the delay time corresponding to the bit value of the control signal into a different resolution.

15. The phase lock loop circuit according to claim 14, wherein:
the plurality of phase comparators include first and second phase comparators;
the first phase comparator outputs the phase signal indicating one of UP and DOWN based on delay or advance of a phase of the output signal with respect to the input signal; and
the second phase comparator outputs the phase signal indicating one of UP, DOWN and HOLD based on delay, advance or equality of the phase of the output signal with respect to the input signal.

16. The phase lock loop circuit according to claim 14, wherein the phase comparator has an automatic calibration circuit which automatically calibrates skews of the input signal and the output signal.

17. The phase lock loop circuit according to claim 16, wherein the phase comparator has:
a first selector circuit which inputs an input signal and an output signal and which selects the input signal in response to input of a calibration signal into a mode terminal and which outputs this selected input signal as a first selection signal;
a second selector circuit which inputs an input signal and which outputs this input signal as a second selection signal;
a deskew circuit which delays the second selection signal output from this second selector circuit;
a data retaining circuit which outputs the phase signal indicating UP or DOWN based on delay or advance of a phase of the first selection signal with respect to the second selection signal; and
the automatic calibration circuit; wherein the automatic calibration circuit has a counter which counts up only when the phase signal indicating UP is received from the data retaining circuit to output a count signal; and
wherein the deskew circuit delays the second selection signal based on the count signal output from the counter.

18. The phase lock loop circuit according to claim 14, further comprising:
a voltage generator which applies different current amounts to the plurality of delay time acquiring sections, respectively, to set the resolution per unit bit of each of the delay time acquiring sections to a different value.

19. The phase lock loop circuit according to claim 18, wherein:
a delay time of a high-order resolution is applied to an output signal by use of a first phase comparator which outputs a phase signal indicating one of UP, DOWN and HOLD, a first counter which receives the phase signal from this first phase comparator and a first delay time acquiring section in which the voltage generator determines the resolution per unit bit in accordance with a comparatively long delay time; and
a delay time of a low-order resolution is applied to an output signal by use of a second phase comparator which outputs a phase signal indicating one of UP and DOWN, a second counter which receives the phase signal from this second phase comparator and a second delay time acquiring section in which the voltage generator determines the resolution per unit bit in accordance with a comparatively short delay time.

20. The phase lock loop circuit according to claim 14, wherein the adding section is connected to current paths indicating the delay time signals output from the plurality of delay time acquiring sections via wired OR, and sends, to the delay time control section, a sum of currents as the delay time added up.

21. The phase lock loop circuit according to claim 14:
wherein the delay time control section has a first transistor through which a current indicating the delay time added up by the adding section flows and a second transistor which is a delay element; and
wherein the first transistor is current-mirror connected to the second transistor.

22. The phase lock loop circuit according to claim 14, wherein the first delay time acquiring section has a small resolution, and the second delay time acquiring section has a large resolution,
the phase lock loop circuit further comprising:
a controller circuit which sends a signal to set a count value to a half value to the first counter and sends a signal to count up or down to the second counter based on the phase signal input from the second phase comparator and/or a digit shift signal input from the first counter,
wherein the first counter is configured to send the digit shift signal to the controller circuit, when the first counter counts up or down based on the phase signal from the first phase comparator and the count value is above or below a predetermined range.

23. The phase lock loop circuit according to claim 22, wherein:
the first counter sends a carry digit shift signal to the controller circuit, when the first counter counts up based on the phase signal input from the first phase comparator and indicating UP and the count value is above the predetermined range;
the controller circuit sends a half signal to the first counter to set the count value to the half value and sends the signal indicating UP to the second counter to count up, when receiving the carry digit shift signal and receiving the phase signal indicating HOLD from the second phase comparator;
the first counter sets the count value to the half value when receiving the half signal; and
the second counter counts up when receiving the signal indicating UP.

24. The phase lock loop circuit according to claim 22, wherein:
the first counter sends a borrow digit shift signal to the controller circuit, when the first counter counts down based on the phase signal input from the first phase comparator and indicating DOWN and the count value is below the predetermined range;
the controller circuit sends the half signal to the first counter to set the count value to the half value and sends the signal indicating DOWN to the second counter to count down, when receiving the borrow digit shift signal and receiving the phase signal indicating HOLD from the second phase comparator;
the first counter sets the count value to the half value when receiving the half signal; and
the second counter counts down when receiving the signal indicating DOWN.

25. The phase lock loop circuit according to, wherein:
the controller circuit sends the half signal to the first counter and sends the signal indicating UP to the second counter, when the phase signal indicating UP is input from the second phase comparator;
the first counter sets the count value to the half value when receiving the half signal; and
the second counter counts up when receiving the signal indicating UP.

26. The phase lock loop circuit according to, wherein:
the controller circuit sends the half signal to the first counter and sends the signal indicating DOWN to the second counter, when the phase signal indicating DOWN is input from the second phase comparator;
the first counter sets the count value to the half value when receiving the half signal; and
the second counter counts down when receiving the signal indicating DOWN.

27. A timing generator comprising:
a delay lock loop circuit including a variable delay circuit constituted by connecting a plurality of stages of logical gates in series; and
a delay selecting section which selects an output of one of the logical gates to output a delay signal,
wherein the delay lock loop circuit is configured as described in claim 1.

28. A timing generator comprising:
a phase lock loop circuit including a variable delay circuit constituted by connecting a plurality of stages of logical gates in series; and
a delay selecting section which selects an output of one of the logical gates to output a delay signal,
wherein the phase lock loop circuit is configured as described in claim 14.

29. A semiconductor tester comprising:
a timing generator which outputs a delay clock signal obtained by delaying a reference clock signal for a predetermined time;
a pattern generator which outputs a test pattern signal in synchronization with the reference clock signal;
a waveform shaping unit which shapes the test pattern signal in accordance with a device to be tested to send the signal to the device to be tested; and
a logical comparator which compares a response output signal of the device to be tested with an expected value data signal,
wherein the timing generator is configured as described in claim 27.

30. A semiconductor integrated circuit comprising:
a plurality of delay lock loop circuits having an equal oscillation frequency; and
wiring lines which distribute reference clock signals having a frequency lower than the oscillation frequency to the delay lock loop circuits,
wherein the delay lock loop circuit is configured as described in claim 1.

31. A semiconductor integrated circuit comprising:
a plurality of phase lock loop circuits having an equal oscillation frequency; and
wiring lines which distribute reference clock signals having a frequency lower than the oscillation frequency to the phase lock loop circuits,
wherein each phase lock loop circuit is configured as described in claim 14.

32. A semiconductor tester comprising:
a timing generator which outputs a delay clock signal obtained by delaying a reference clock signal for a predetermined time;
a pattern generator which outputs a test pattern signal in synchronization with the reference clock signal;
a waveform shaping unit which shapes the test pattern signal in accordance with a device to be tested to send the signal to the device to be tested; and
a logical comparator which compares a response output signal of the device to be tested with an expected value data signal,
wherein the timing generator is configured as described in claim 28.
